(19) United States
(12) Patent Application Publication
(10) Pub. No.: US 2023/0116998 A1
(43) Pub. Date: Apr. 20, 2023

(54) COMPUTER-READABLE RECORDING MEDIUM STORING CLOSED MAGNETIC CIRCUIT CALCULATION PROGRAM, CLOSED MAGNETIC CIRCUIT CALCULATION METHOD, AND INFORMATION PROCESSING APPARATUS

(71) Applicant: FUJITSU LIMITED, Kawasaki-shi (JP)

(72) Inventors: Minoru HOSHINA, Kawasaki (JP); Masaki KAZAMA, Kawasaki (JP)

(73) Assignee: FUJITSU LIMITED, Kawasaki-shi (JP)

(21) Appl. No.: 17/851,085

(22) Filed: Jun. 28, 2022

(30) Foreign Application Priority Data
Oct. 20, 2021 (JP) 2021-171741

(51) Int. Cl. H01F 13/00; H01F 7/02

(52) U.S. Cl. CPC H01F 13/003; H01F 7/0273

(57) ABSTRACT

A dosed magnetic circuit calculation program for a computer. The program includes steps of calculating, based on a temporary dosed magnetic circuit curve indicating a relationship between an external magnetic field and magnetization of a permanent magnet in a closed magnetic circuit environment, a first open magnetic circuit curve indicating a relationship between the external magnetic field and the magnetization of the permanent magnet, calculating a magnetic field difference between the temporary closed magnetic circuit curve and the first open magnetic circuit curve, updating the temporary closed magnetic circuit curve with a magnetization curve shifted in the external magnetic field direction by the magnetic field difference from a second open magnetic circuit curve obtained by measuring the magnetization of the permanent magnet in an open magnetic circuit environment, and repeating the process until an error between the first and the second open magnetic circuit curves satisfies a predetermined condition.

### CROSS-REFERENCE TO RELATED APPLICATION

This application is based upon and claims the benefit of priority of the prior Japanese Patent Application No. 2021-171741, filed on Oct. 20, 2021, the entire contents of which are incorporated herein by reference.

### FIELD

The embodiments discussed herein are related to a dosed magnetic circuit calculation program, a dosed magnetic circuit calculation method, and an information processing apparatus.

### BACKGROUND

Permanent magnets are used in various industrial products. Magnetization is one of physical quantities that represent characteristics of the permanent magnets. The magnetization of the permanent magnets changes when an external magnetic field is applied. The degree of magnetization of the permanent magnets according to the external magnetic field is represented by a magnetization curve. For example, the magnetic characteristics of the permanent magnets can be known from the magnetization curve.

Note that the magnetization of a permanent magnet is affected by the magnetic field (diamagnetic field) created by the magnetization of the permanent magnet itself. The diamagnetic field does not represent a physical characteristic of the permanent magnet because its value changes depending on the shape of the permanent magnet and a measurement environment. The influence of the diamagnetic field of the permanent magnet can be excluded by measuring the magnetization in a closed magnetic circuit environment (an environment in which magnetic field lines do not leak to an outside). Therefore, when measuring the magnetic characteristics of the permanent magnet, for example, a measuring device (dosed magnetic circuit measuring device) that can create a measurement environment for a closed magnetic circuit is used.

However, although the closed magnetic circuit measuring device can exclude the diamagnetic field, the closed magnetic circuit measuring device cannot measure the magnetic characteristics of a permanent magnet having a strong magnetic force such as a neodymium magnet due to insufficient strength of the external magnetic field that can be created, Therefore, measurement of the magnetic characteristics in the closed magnetic circuit is not versatile. Therefore, in many cases, the magnetic characteristics of the permanent magnet are obtained by correcting the magnetization measured in an environment of an open magnetic circuit affected by the diamagnetic field (an environment where the magnetic field lines leak to the outside) so as to exclude the influence of the diamagnetic field using a predetermined correction formula.

As a technique for measuring the magnetic characteristics, for example, a magnet characteristic measuring method capable of accurately measuring the magnetic characteristics of a magnet by removing a resonance frequency component from a detected voltage waveform has been proposed. Furthermore, a closed magnetic circuit calculation method for correcting a measurement result in an open magnetic circuit environment by numerical value calculation by a finite element method using a mesh model of a permanent magnet and calculating the magnetic characteristics excluding the influence of the diamagnetic field with high accuracy has also been proposed.

Japanese Laid-open Patent Publication No. 2016-102752 and Japanese Laid-open Patent Publication No. 2019-215226 are disclosed as related art.

### SUMMARY

According to an aspect of the embodiments, a recording medium storing a closed magnetic circuit calculation program for causing a computer to execute a process including: calculating, on a basis of a temporary closed magnetic circuit curve that indicates a relationship between an external magnetic field and magnetization of a permanent magnet in a closed magnetic circuit environment, a first open magnetic circuit curve that indicates a relationship between the external magnetic field and the magnetization of the permanent magnet in a case of applying an influence of a diamagnetic field to the external magnetic field, using a three-dimensional model that represents the permanent magnet; calculating a magnetic field difference indicating a difference between the temporary closed magnetic circuit curve and the first open magnetic circuit curve in an external magnetic field direction according to the magnetization; updating the temporary closed magnetic circuit curve with a magnetization curve shifted in the external magnetic field direction by the magnetic field difference from a second open magnetic circuit curve obtained by measuring the magnetization of the permanent magnet according to the external magnetic field in an open magnetic circuit environment; and repeating the calculation of the first open magnetic circuit curve, the calculation of the magnetic field difference, and the update of the temporary closed magnetic circuit curve until an error between the first open magnetic circuit curve and the second open magnetic circuit curve satisfies a predetermined condition.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a closed magnetic circuit calculation method according to a first embodiment;

FIG. 2 is a diagram illustrating a system configuration example according to a second embodiment;

FIG. 3 is a diagram illustrating an example of a magnetic characteristic measuring device;

FIG. 4 is a diagram illustrating an example of hardware of a computer;

FIG. 5 is a block diagram illustrating an example of a magnetic characteristic calculation function in a computer;

FIG. 6 is a diagram illustrating an example of a measurement result stored in a storage unit;

FIG. 7 is a diagram illustrating an example of a magnetic field generated during magnetic characteristic measurement;

FIG. 8 is a graph illustrating an example of a magnetization curve;

FIG. 9 is graphs illustrating a difference between an open magnetic circuit curve and a closed magnetic circuit curve;

FIG. 10 is a diagram illustrating an outline of a procedure for calculating a closed magnetic circuit curve;

FIG. 11 is a diagram illustrating an example of a calculation result by correcting a temporary closed magnetic circuit curve in a magnetization direction;

FIG. 12 is a diagram illustrating an example of a calculation result by correcting a temporary closed magnetic circuit curve in an external magnetic field direction;

FIG. 13 is a diagram illustrating an example of a meandering closed magnetic circuit curve;

FIG. 14 is a diagram illustrating an example of a correction method for a closed magnetic circuit curve;

FIG. 15 is a diagram illustrating an example of a magnetization calculation method;

FIG. 16 is a diagram illustrating an example of calculating average magnetization;

FIG. 17 is a diagram illustrating an example of a correction method for a temporary dosed magnetic circuit curve;

FIG. 18 is a diagram illustrating an example of a magnetic field difference calculation method;

FIG. 19 is a diagram illustrating an example of a correction method to a one-valued function;

FIG. 20 is a first half of a flowchart illustrating an example of a procedure of processing for correcting a temporary closed magnetic circuit curve;

FIG. 21 is a latter half of the flowchart illustrating an example of a procedure of processing for correcting a temporary closed magnetic circuit curve; and

FIG. 22 is a flowchart illustrating a procedure of processing for calculating a magnetic field difference between a closed magnetic circuit curve and an open magnetic circuit curve.

### DESCRIPTION OF EMBODIMENTS

In an existing technique of correcting a measurement result in an open magnetic circuit environment, there are some cases where a solution that does not satisfy monotonicity (magnetization decreases when a magnetic field decreases) of a demagnetization curve (part of a second quadrant of a magnetization curve) is calculated. For example, the solution that does not satisfy the monotonicity is likely to be calculated in a case of calculating magnetic characteristics of a magnet made of industrially important processing deterioration or non-uniform material. It is known that the monotonicity of the demagnetization curve is satisfied in an actual physical phenomenon, and the calculation result of magnetic characteristics contrary to this physical phenomenon is a non-physical solution. Therefore, in a case where the solution that does not satisfy the monotonicity of the demagnetization curve is calculated, the solution does not represent accurate magnetic characteristics of a permanent magnet.

In one aspect, the present case aims to suppress calculation of a demagnetization curve that does not satisfy the monotonicity.

Hereinafter, the present embodiments will be described with reference to the drawings. Note that each of the embodiments may be implemented in combination with a plurality of embodiments as long as no contradiction arises.

### First Embodiment

First, a first embodiment will be described. The first embodiment is a closed magnetic circuit calculation method that can suppress calculation of a demagnetization curve that does not satisfy monotonicity when the closed magnetic circuit curve of a permanent magnet is obtained by calculation. Note that, in the following description, in a case of referring to the monotonicity of a magnetization curve (including a closed magnetic circuit curve and an open magnetic circuit curve), it is assumed that the case means the monotonicity of the part of the demagnetization curve of the magnetization curve.

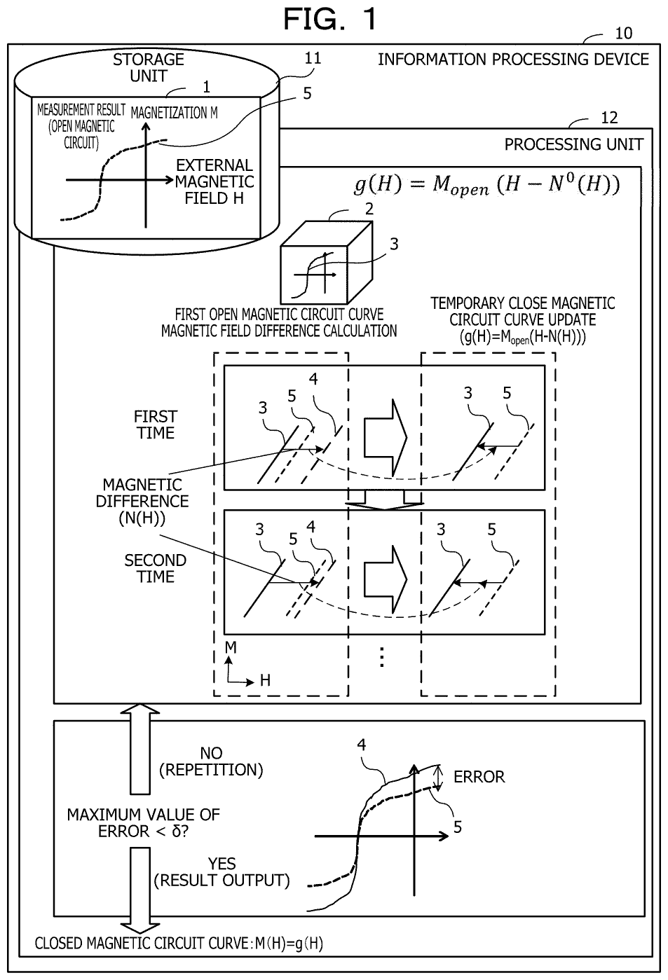

FIG. 1 is a diagram illustrating an example of a closed magnetic circuit calculation method according to a first embodiment. FIG. 1 illustrates an example of a case where the closed magnetic circuit calculation method is performed by an information processing device 10. The information processing device 10 can implement the closed magnetic circuit calculation method by executing, for example, a closed magnetic circuit calculation program.

The information processing device 10 includes a storage unit 11 and a processing unit 12, The storage unit 11 is, for example, a memory or a storage device included in the information processing device 10, The processing unit 12 is, for example, a processor or an arithmetic circuit included in the information processing device 10.

The storage unit 11 stores a measurement result 1 of when measuring magnetization of a permanent magnet according to an external magnetic field in an open magnetic circuit environment. The measurement result 1 contains, for example, a plurality of data indicating a value of the external magnetic field and a value of the magnetization of the permanent magnet at that time. Each data indicates a discrete point on a coordinate system in which the external magnetic field and the magnetization serve as coordinate axes. A curve that smoothly connects the plurality of discrete points indicated in the measurement result 1 is the open magnetic circuit curve (second open magnetic circuit curve 5) obtained as the measurement result.

The processing unit 12 calculates a closed magnetic circuit curve of the permanent magnet on the basis of the second open magnetic circuit curve 5 and a three-dimensional model 2 in which the permanent magnet to be measured is modeled by a mesh model or the like. The three-dimensional model 2 represents the shape of the permanent magnet, and a diamagnetic field according to the shape of the permanent magnet can be correctly calculated by using the three-dimensional model 2. Note that the processing unit 12 calculates the closed magnetic circuit curve by the following procedure so that the calculated closed magnetic circuit curve satisfies the monotonicity.

For example, the processing unit 12 first generates a temporary closed magnetic circuit curve 3 representing a relationship between the external magnetic field and the magnetization of the permanent magnet in the closed magnetic circuit environment. For example, the processing unit 12 defines a function “g(H)=Mₒₚₑₙ(H N⁰ (H))” when a function for obtaining the magnetization from the external magnetic field on the basis of the second open magnetic circuit curve 5 is “Mₒₚₑₙ(H)” (H is the external magnetic field). “N⁰ (H)” is an initial value of the value of the diamagnetic field for each value of the external magnetic field. The initial value of the magnetic field obtained by “N⁰ (H)” can be set arbitrarily. As the initial value, for example, “N⁰ (H)=o” may be set for all of external magnetic fields. In that case, an initial state of the temporary closed magnetic circuit curve 3 coincides with the second open magnetic circuit curve 5.

After defining the temporary closed magnetic circuit curve 3 in the initial state, the processing unit 12 calculates a first open magnetic circuit curve 4 representing the relationship between the external magnetic field and the magnetization of the permanent magnet in a case of adding the influence of the diamagnetic field to the external magnetic field on the basis of the temporary closed magnetic circuit curve 3, using the three-dimensional model 2 representing the permanent magnet. In a case where the three-dimensional model 2 is a mesh model in which an area of the permanent magnet is divided into a plurality of meshes, the processing unit 12 calculates the magnetization according to the external magnetic field for each mesh, for example. Then, the processing unit 12 sets an average of the magnetization of the meshes according to the external magnetic field as the magnetization of the permanent magnet.

After calculating the first open magnetic circuit curve 4, the processing unit 12 calculates a magnetic field difference indicating a difference in an external magnetic field direction according to the magnetization between the temporary closed magnetic circuit curve 3 and the first open magnetic circuit curve 4. The magnetic field difference is obtained by, for example, subtracting the value of the external magnetic field of the temporary closed magnetic circuit curve 3 from the value of the external magnetic field of the first open magnetic circuit curve 4 at the time of the magnetization for each value of magnetization. A function indicating the magnetic field difference can be expressed by the function “N(H)” in which the external magnetic field is a variable H For example, the value of the magnetization corresponding to the value of one external magnetic field is determined on the basis of the second open magnetic circuit curve 5 indicated in the measurement result 1. The magnetic field difference corresponding to the value of the magnetization becomes the value of the function “N(H)” corresponding to the value of one external magnetic field.

After calculating the magnetic field difference, the processing unit 12 updates the temporary closed magnetic circuit curve 3 with a magnetization curve obtained by shifting the second open magnetic circuit curve 5 in the external magnetic field direction by the magnetic field difference. The magnetization curve can be expressed by, for example, a function “g(H) Mₒₚₑₙ(H−N(H))”.

Then, the processing unit 12 repeats the calculation of the first open magnetic circuit curve 4, the calculation of the magnetic field difference, and the update of the temporary closed magnetic circuit curve 3 until an error between the first open magnetic circuit curve 4 and the second open magnetic circuit curve 5 satisfies a predetermined condition. The predetermined condition of the error is that, for example, a maximum value of the difference in magnetization (magnetization difference) between the first open magnetic circuit curve 4 and the second open magnetic circuit curve 5 for each external magnetic field is less than a predetermined threshold value δ. As the predetermined condition of the error, for example, a condition that the maximum value of the magnetic field difference is less than a predetermined threshold value may be used.

The error between the first open magnetic circuit curve 4 and the second open magnetic circuit curve 5 is reduced every time the calculation of the first open magnetic circuit curve 4, the calculation of the magnetic field difference, and the update of the temporary closed magnetic circuit curve 3 are repeated. Then, the temporary closed magnetic circuit curve 3 of when the error between the first open magnetic circuit curve 4 and the second open magnetic circuit curve 5 satisfies the predetermined condition represents the magnetization curve of when the influence of the diamagnetic field is excluded from the second open magnetic circuit curve 5 indicating the measurement result. Therefore, the processing unit 12 outputs the temporary closed magnetic circuit curve 3 of when the error between the first open magnetic circuit curve 4 and the second open magnetic circuit curve 5 satisfies the predetermined condition as the closed magnetic circuit curve “M(H)” indicating the magnetic characteristics of the permanent magnet in the closed magnetic circuit environment.

In this way, the processing unit 12 generates the temporary dosed magnetic circuit curve 3 by correcting the second open magnetic circuit curve 5 indicated in the measurement result 1 in the external magnetic field direction. By making a correction in the external magnetic field direction, it is suppressed that the monotonicity of the closed magnetic circuit curve obtained as a solution is not satisfied. For example, in a case of making a correction in a magnetization direction, the temporary closed magnetic circuit curve tends to be jagged in the magnetization direction. As a result, the closed magnetic circuit curve obtained as a solution may not satisfy the monotonicity. In contrast, by making a correction in the external magnetic field direction, it is possible to suppress the temporary closed magnetic circuit curve from becoming jagged in the magnetization direction. As a result, the monotonicity of the closed magnetic circuit curve obtained as a solution is maintained.

Moreover, if the temporary closed magnetic circuit curve generated in the process of repeated calculation processing does not satisfy the monotonicity, it takes time for the solution to converge, and a total calculation time becomes long. In contrast, by generating the temporary closed magnetic circuit curve that satisfies the monotonicity by making a correction in the external magnetic field direction, it is possible to cause the solution to efficiently converge and shorten the calculation time.

Note that when measurement of the magnetization is performed in the open magnetic circuit environment with high accuracy, the second open magnetic circuit curve 5 indicated in the measurement result 1 satisfies the monotonicity. Then, the temporary closed magnetic circuit curve 3 generated by making a correction in the external magnetic field direction using the magnetization difference with reference to the second open magnetic circuit curve 5 also satisfies the monotonicity. However, if a measurement error included in the measurement result 1 is large, the temporary closed magnetic circuit curve may be jagged in the external magnetic field direction even if the correction is made in the external magnetic field direction. Therefore, in a case where a magnetization curve that is not a one-valued function (a function in which one magnetization is determined with respect to the value of the external magnetic field) is generated, the processing unit 12 may correct the magnetization curve to become a one-valued function. In this case, the processing unit 12 corrects the temporary closed magnetic circuit curve 3 to the magnetization curve corrected to the one-valued function.

The magnetization curve generated using the magnetic field difference is generated by connecting a plurality of discrete points (points arranged at intervals) with a smooth curve, for example. At this time, the processing unit 12 can correct the magnetization curve by moving positions of some of the discrete points. For example, in a case where the value of the external magnetic field of a second discrete point is smaller than the value of the external magnetic field of a first discrete point, the second discrete point having the value of magnetization larger than the value of magnetization of the first discrete point, among the plurality of discrete points on the magnetization curve, the processing unit 12 corrects the value of the external magnetic field of the second discrete point to be larger than the value of the external magnetic field of the first discrete point. Thereby, the monotonicity of the temporary closed magnetic circuit curve 3 is reliably maintained.

Furthermore, the processing unit 12 may set an upper limit so that a correction amount of the value of the external magnetic field of the second discrete point is not too large. For example, when correcting the value of the external magnetic field of the second discrete point, the processing unit 12 may correct the value of the external magnetic field of the second discrete point to a value smaller than the value of the external magnetic field of any third discrete point having the value of the external magnetic field larger than that of the first discrete point and having the value of the magnetization larger than that of the second discrete point. Thereby, it is possible to suppress occurrence of a situation in which the correction amount of the position of the discrete point is too large and the one-valued function is not satisfied even after the correction.

When calculating the magnetic field difference, the processing unit 12 calculates, with reference to a first point on the second open magnetic circuit curve 5 (for example, a point where the external magnetic field and the magnetization are measured), the magnetic field difference corresponding to the value of magnetization of the first point, for example. In this case, the processing unit 12 calculates, for the first point on the second open magnetic circuit curve 5, a difference value between the value of the external magnetic field of the second point and the value of the external magnetic field of a third point, the second point being located on the temporary closed magnetic circuit curve 3 and having the equal value of magnetization to the first point, and the third point being located on the first open magnetic circuit curve 4 and having the equal value of magnetization to the first point. Then, the processing unit 12 generates a magnetization curve passing through a fourth point indicated by the value of the external magnetic field obtained by changing the value of the external magnetic field of the first point on the second open magnetic circuit curve 5 by the difference value calculated with respect to the first point, and the value of magnetization of the first point.

By obtaining the magnetic field difference for each magnetization value of the point on the second open magnetic circuit curve 5 in this way, the point serving as a reference for calculating the magnetic field difference coincides with the point serving as a reference when making a correction by the magnetic field difference when updating the temporary closed magnetic circuit curve 3. As a result, it is possible to accurately generate the temporary closed magnetic circuit curve 3 on the basis of the magnetic field difference.

### Second Embodiment

Next, a second embodiment will be described. The second embodiment is a system that calculates magnetic characteristics in a closed magnetic circuit environment on the basis of measurement results of a magnetic characteristic measuring device that performs measurement in an open magnetic circuit environment.

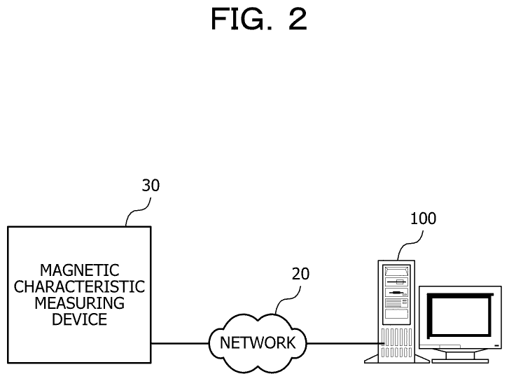

FIG. 2 is a diagram illustrating a system configuration example according to the second embodiment, A magnetic characteristic measuring device 30 is connected to a computer 100 via a network 20. The magnetic characteristic measuring device 30 is a device capable of measuring magnetization of a permanent magnet in the open magnetic circuit environment. The computer 100 calculates the magnetic characteristics in the dosed magnetic circuit environment on the basis of the measurement results of the magnetic characteristics in the open magnetic circuit environment in the magnetic characteristic measuring device 30,

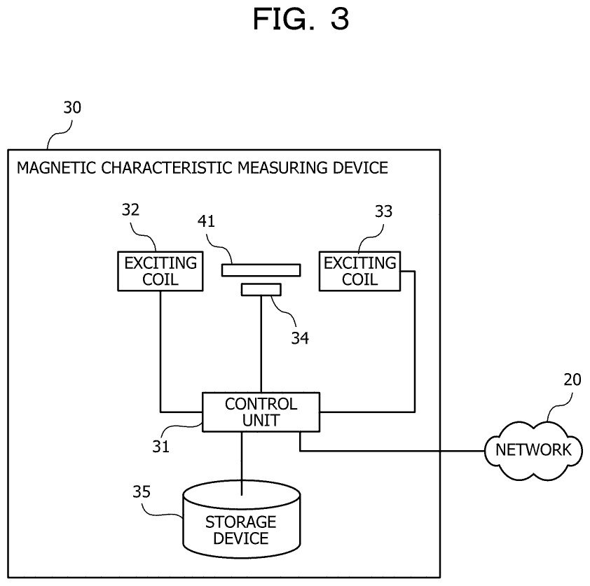

FIG. 3 is a diagram illustrating an example of the magnetic characteristic measuring device. The magnetic characteristic measuring device 30 measures the magnetic characteristics of a permanent magnet 41 prepared as a sample under control of a control unit 31. For example, the control unit 31 generates an external magnetic field around the permanent magnet 41 by a plurality of exciting coils 32 and 33. The strength of the external magnetic field is expressed in units of ampere per meter (Aim), oersted (Oe), or the like.

The control unit 31 detects a magnetic field generated by magnetization of the permanent magnet 41 using a magnetic field sensor 34. Then, the control unit 31 measures the magnetization of the permanent magnet according to the external magnetic field on the basis of the detected magnetic field. The magnetization is expressed in units of Gauss (G) or the like.

For example, the control unit 31 generates a strong external magnetic field and magnetizes the permanent magnet 41 until saturation magnetization is achieved. Then, the magnetic characteristic measuring device 30 measures the magnetization of the permanent magnet 41 according to the external magnetic field while reducing the strength of the external magnetic field, After the strength of the external magnetic field becomes “0”, the magnetic characteristic measuring device 30 strengthens the external magnetic field (opposing magnetic field) in a direction opposite to that at the time of magnetization, and measures the magnetization of the permanent magnet 41 according to the external magnetic field. Thereby, a measurement result indicating a demagnetization curve can be obtained.

The control unit 31 stores a measured magnetization value as a measurement result in a storage device 35, Furthermore, the control unit 31 transmits the measurement result to the computer 100 via the network 20 in response to a request from the computer 100.

Note that FIG. 3 illustrates two exciting coils 32 and 33 in the magnetic characteristic measuring device 30, but there are also exciting coils (not illustrated) around the permanent magnet 41. Furthermore, the magnetic characteristic measuring device 30 may be provided with a magnetic field sensor in addition to the magnetic field sensor 34 illustrated in FIG. 3.

The computer 100 that has received the measurement result from the magnetic characteristic measuring device 30 calculates the magnetic characteristics in the closed magnetic circuit environment on the basis of the measurement result.

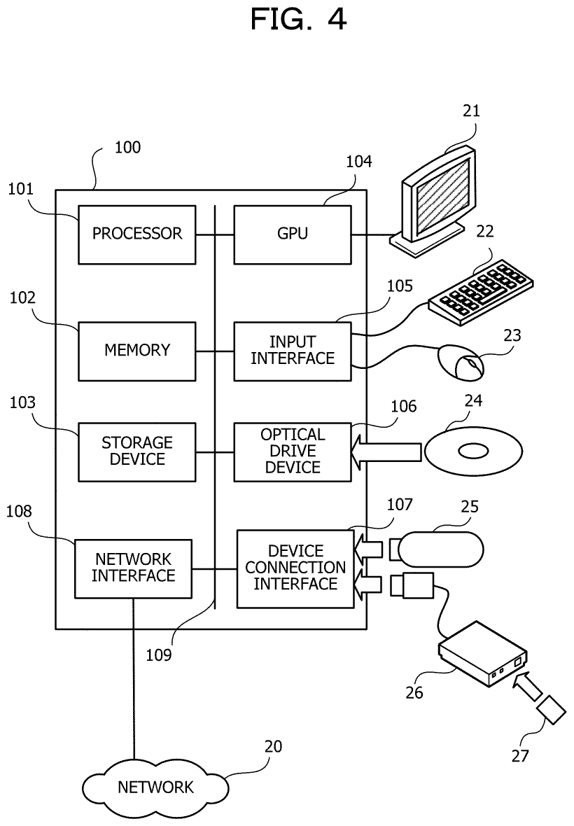

FIG. 4 is a diagram illustrating an example of hardware of the computer. The entire device of the computer 100 is controlled by a processor 101, A memory 102 and a plurality of peripheral devices are connected to the processor 101 via a bus 109. The processor 101 may be a multiprocessor. The processor 101 is, for example, a central processing unit (CPU), a micro processing unit (MPU), or a digital signal processor (DSP). At least a part of functions implemented by the processor 101 executing a program may be implemented by an electronic circuit such as an application specific integrated circuit (ASIC) or a programmable logic device (PLD).

The memory 102 is used as a main storage device of the computer 100. The memory 102 temporarily stores at least a part of an operating system (OS) program and an application program to be executed by the processor 101. Furthermore, the memory 102 stores various types of data to be used in processing by the processor 101. As the memory 102, for example, a volatile semiconductor storage device such as a random access memory (RAM) is used.

Examples of the peripheral devices connected to the bus 109 include a storage device 103, a graphics processing unit (GPU) 104, an input interface 105, an optical drive device 106, a device connection interface 107, and a network interface 108.

The storage device 103 writes and reads data electrically or magnetically in and from a built-in recording medium. The storage device 103 is used as an auxiliary storage device of the computer 100, The storage device 103 stores an OS program, an application program, and various types of data. Note that, as the storage device 103, for example, a hard disk drive (HDD) or a solid state drive (SSD) may be used.

The GPU 104 is an arithmetic unit that performs image processing, and is also called a graphic controller. A monitor 21 is connected to the GPU 104. The GPU 104 causes an image to be displayed on a screen of the monitor 21 in accordance with an instruction from the processor 101. Examples of the monitor 21 include a display device using organic electro luminescence (EL), a liquid crystal display device, and the like.

To the input interface 105, a keyboard 22 and a mouse 23 are connected. The input interface 105 transmits signals transmitted from the keyboard 22 and the mouse 23 to the processor 101. Note that the mouse 23 is an example of a pointing device, and another pointing device may also be used. Examples of the another pointing device include a touch panel, a tablet, a touch pad, a track ball, and the like.

The optical drive device 106 uses laser light or the like to read data recorded in an optical disk 24 or write data to the optical disk 24. The optical disk 24 is a portable recording medium in which data is recorded to be readable by reflection of light. Examples of the optical disk 24 include a digital versatile disc (DVD), a DVD-RAM, a compact disc read only memory (CD-ROM), a CD-recordable (R)/rewritable (RW), and the like.

The device connection interface 107 is a communication interface for connecting the peripheral devices to the computer 100. For example, a memory device 25 and a memory reader/writer 26 may be connected to the device connection interface 107. The memory device 25 is a recording medium equipped with a communication function with the device connection interface 107. The memory reader; writer 26 is a device that writes data in a memory card 27 or reads data from the memory card 27. The memory card 27 is a card type recording medium.

The network interface 108 is connected to the network 20. The network interface 108 transmits/receives data to/from another computer or a communication device via the network 20. The network interface 108 is a wired communication interface connected to a wired communication device such as a switch or a router with a cable, for example. Furthermore, the network interface 108 may be a wireless communication interface that is connected to and communicates with a wireless communication device such as a base station or an access point by radio waves.

The computer 100 may implement a processing function of the second embodiment with the above-described hardware. Note that the information processing device 10 described in the first embodiment may be implemented by hardware similar to the computer 100 illustrated in FIG. 4.

The computer 100 implements the processing function of the second embodiment by executing, for example, a program recorded in a computer-readable recording medium. The program in which processing content to be executed by the computer 100 is described can be recorded in various recording media. For example, the program to be executed by the computer 100 may be stored in the storage device 103. The processor 101 loads at least a part of the program in the storage device 103 into the memory 102 and executes the program. It is also possible to record the program to be executed by the computer 100 in a portable recording medium such as the optical disk 24, the memory device 25, or the memory card 27. The program stored in the portable recording medium may be executed after being installed in the storage device 103 under the control of the processor 101, for example. Furthermore, the processor 101 may read the program directly from the portable recording medium, and execute the program.

With the computer 100 having such a hardware configuration, the magnetic characteristics of the permanent magnet 41 can be calculated with high accuracy.

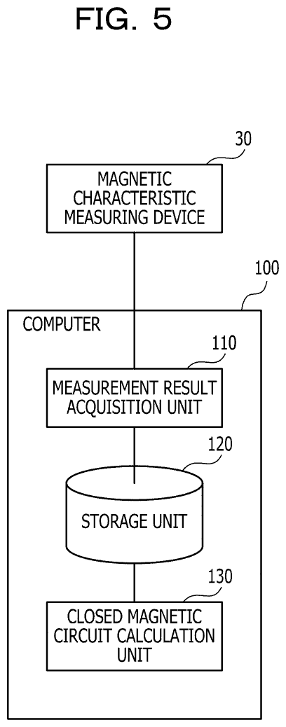

FIG. 5 is a block diagram illustrating an example of a magnetic characteristic calculation function in the computer. The computer 100 has a measurement result acquisition unit 110, a storage unit 120, and a dosed magnetic circuit calculation unit 130.

The measurement result acquisition unit 110 acquires the measurement result in the open magnetic circuit environment from the magnetic characteristic measuring device 30 via the network 20. The measurement result acquisition unit 110 stores the acquired measurement result in the storage unit 120.

The storage unit 120 stores the measurement result. The storage unit 120 is, for example, a part of a storage area of the storage device 103.

The closed magnetic circuit calculation unit 130 corrects the measurement result by the magnetic characteristic measuring device 30 so as to exclude an influence of a diamagnetic field, and calculates a dosed magnetic circuit curve representing the magnetic characteristics in the closed magnetic circuit environment. For example, the closed magnetic circuit calculation unit 130 calculates a magnetic field difference as a correction coefficient of the permanent magnet 41 used as a sample, for excluding the influence of the diamagnetic field from the measurement result, on the basis of the measurement result in the open magnetic circuit environment. For example, the closed magnetic circuit calculation unit 130 calculates an appropriate magnetic field difference for each strength of the external magnetic field at the time of measurement. Next, the closed magnetic circuit calculation unit 130 calculates a closed magnetic circuit curve representing the magnetic characteristics of the permanent magnet 41 in the closed magnetic circuit by correcting magnetization data of the permanent magnet 41 indicated in the measurement result with the magnetic field difference. The dosed magnetic circuit calculation unit 130 outputs data of the calculated closed magnetic circuit curve. For example, the closed magnetic circuit calculation unit 130 stores the data of the closed magnetic circuit curve in the storage device 103. Furthermore, the closed magnetic circuit calculation unit 130 displays the calculated closed magnetic circuit curve as a graph on the monitor 21.

Note that the function of each of the measurement result acquisition unit 110 and the closed magnetic circuit calculation unit 130 illustrated in FIG. 5 can be implemented by, for example, causing the computer to execute a program module corresponding to the element.

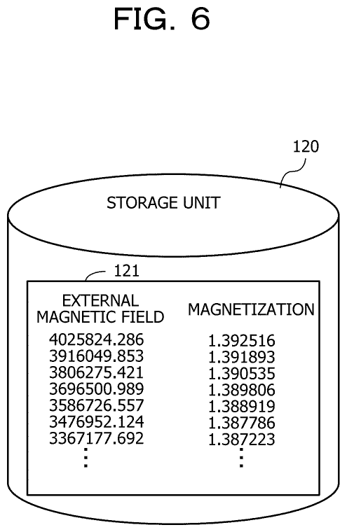

FIG. 6 is a diagram illustrating an example of the measurement result stored in the storage unit. In a measurement result 121, a value of magnetization (kG) of the permanent magnet 41 in an external magnetic field (A; m) is set for each external magnetic field at the time of measurement.

The measurement result 121 acquired from the magnetic characteristic measuring device 30 represents the magnetic characteristics including the influence of the diamagnetic field. The set of the value of the external magnetic field and the value of the magnetization illustrated in the measurement result 121 indicates a discrete point on a coordinate system where the external magnetic field and the magnetization serve as axes. A curve passing through a plurality of discrete points obtained from the measurement result 121 is an open magnetic circuit curve representing the measurement result.

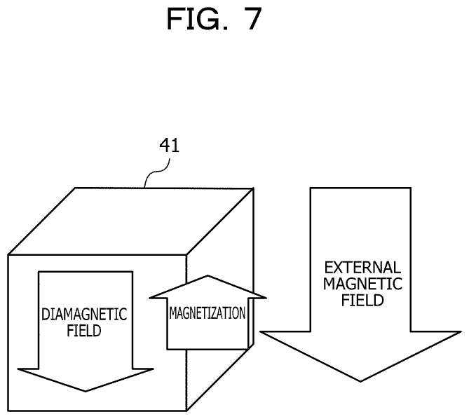

FIG. 7 is a diagram illustrating an example of a magnetic field generated during the magnetic characteristic measurement. In the example of FIG. 7, the external magnetic field is generated in a Z-axis direction (an up-down direction in FIG. 7) of a space in which the permanent magnet 41 is arranged. The strength of magnetization of the permanent magnet 41 changes due to the influence of the external magnetic field. Furthermore, when the permanent magnet 41 is magnetized, a diamagnetic field is generated inside the permanent magnet 41. The strength of magnetization of the permanent magnet 41 is also affected by the diamagnetic field created by its own magnetization.

The measurement result 121 in the open magnetic circuit environment indicates the magnetic characteristics of the permanent magnet including the influence of the diamagnetic field. The magnetization curve representing such magnetic characteristics is the open magnetic circuit curve. Meanwhile, in a case where the magnetic characteristics can be measured in the dosed magnetic circuit environment, a magnetization curve excluding the influence of the diamagnetic field can be obtained. Such a magnetization curve is the dosed magnetic circuit curve. The presence or absence of the influence of the diamagnetic field strongly appears in a demagnetization curve of the magnetization curve.

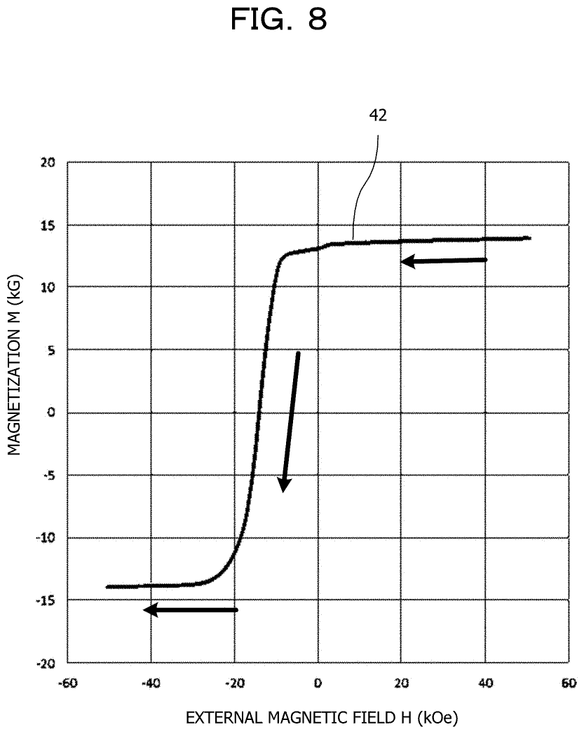

FIG. 8 is a graph illustrating an example of the magnetization curve. FIG. 8 illustrates a graph in which a horizontal axis represents the strength of the magnetic field (external magnetic field) applied from the outside and a vertical axis represents the strength of the magnetization of the permanent magnet 41. The example of FIG. 8 illustrates the magnetic characteristics of when the external magnetic field is weakened and after the external magnetic field becomes “0”, the external magnetic field (opposing magnetic field) is strengthened in a direction opposite to the magnetization direction, in the magnetization curve 42. The portion indicating the magnetic characteristics from when the magnetization of the permanent magnet 41 is weakened by the opposing magnetic field to when the magnetization becomes 0 in the magnetization curve is the demagnetization curve. The demagnetization curve is represented in the second quadrant of the graph (the area where the external magnetic field is negative and the magnetization is positive).

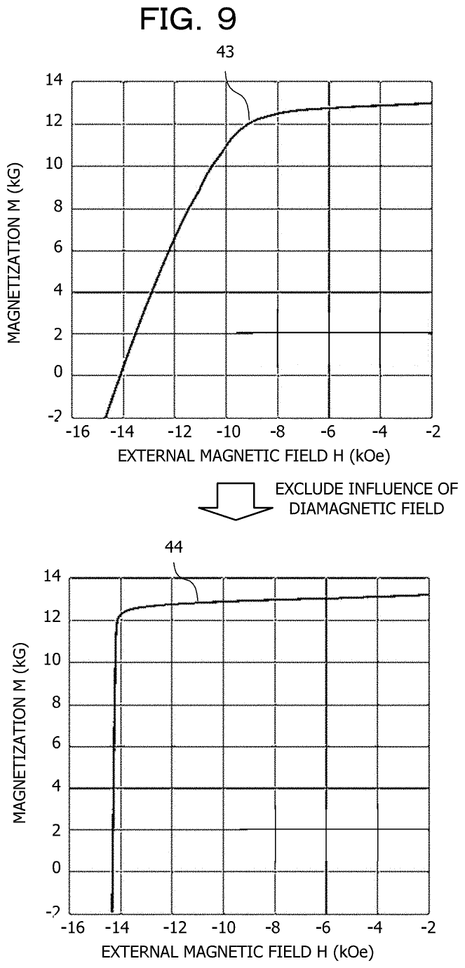

FIG. 9 is graphs illustrating a difference between an open magnetic circuit curve and a closed magnetic circuit curve. FIG. 9 illustrates an open magnetic circuit curve 43 (demagnetization curve portion) in the upper row, and a closed magnetic circuit curve 44 (demagnetization curve portion) in the lower row. In the open magnetic circuit environment, the diamagnetic field in the same direction as the external magnetic field is generated, as illustrated in FIG. 7. Therefore, the open magnetic circuit curve 43 has a different shape from the closed magnetic circuit curve 44 excluding the influence of the diamagnetic field.

Therefore, the computer 100 is used to correct the open magnetic circuit curve 43 to obtain the closed magnetic circuit curve 44, For example, the computer 100 corrects the measurement result in the open magnetic circuit environment by numerical value calculation (simulation) by a finite element method using a mesh model of the permanent magnet and calculates the magnetic characteristics excluding the influence of the diamagnetic field with high accuracy.

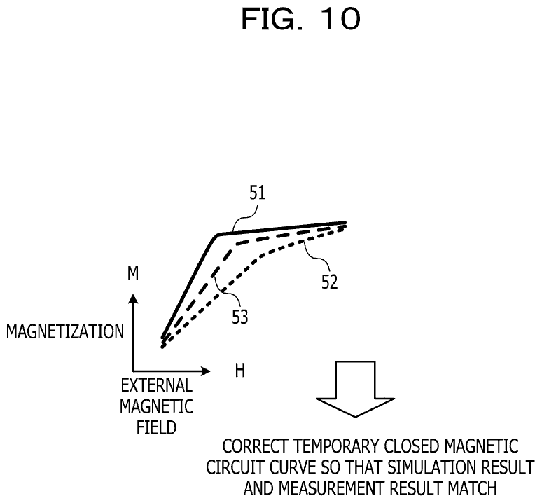

FIG. 10 is a diagram illustrating an outline of a procedure for calculating the closed magnetic circuit curve. The closed magnetic circuit calculation unit 130 generates a temporary closed magnetic circuit curve 51. Then, the closed magnetic circuit calculation unit 130 performs a simulation of applying the influence of the diamagnetic field to the temporary closed magnetic circuit curve 51, using the temporary closed magnetic circuit curve 51 as input data for the simulation. An open magnetic circuit curve 52 is obtained as a calculation result of the simulation. The closed magnetic circuit calculation unit 130 repeats correction of the temporary closed magnetic circuit curve 51 so that the open magnetic circuit curve 52 obtained by the simulation matches an open magnetic circuit curve 53 obtained as a measurement result.

In the case where the open magnetic circuit curve 52 obtained as a calculation result of the simulation matches the open magnetic circuit curve 53 of the measurement result within a range of a predetermined error, the temporary closed magnetic circuit curve 51 used to generate the open magnetic circuit curve 52 represents the magnetic characteristics in which the influence of the diamagnetic field is removed.

Here, as a method of correcting the temporary dosed magnetic circuit curve 51, a method of making a correction in the magnetization direction and a method of making a correction in the external magnetic field direction are conceivable.

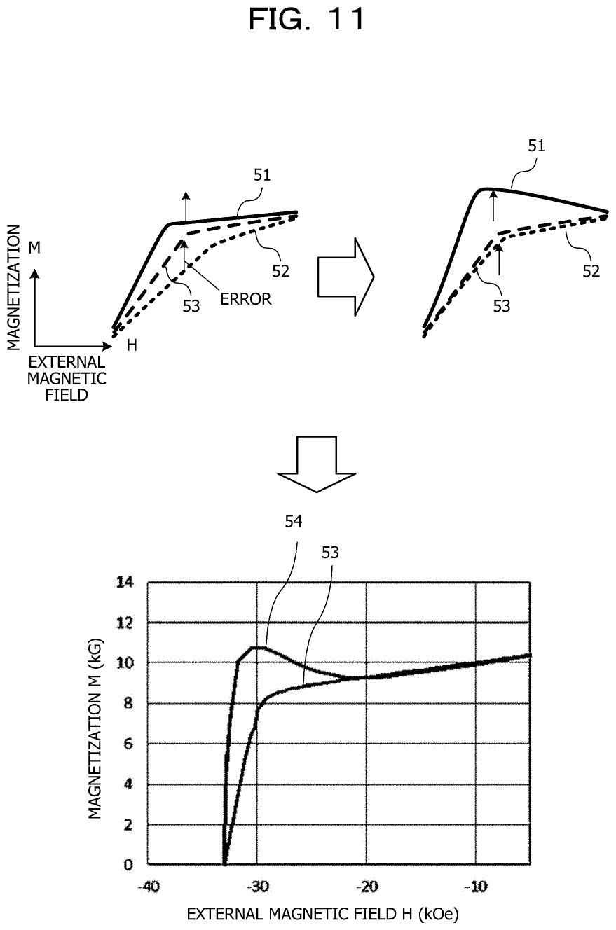

FIG. 11 is a diagram illustrating an example of a calculation result by correcting the temporary closed magnetic circuit curve in the magnetization direction. In the example of FIG. 11, the temporary closed magnetic circuit curve 51 is expressed by a tanh function (hyperbolic tangent function). The open magnetic circuit curve 52 of the calculation result of the simulation is shifted in a direction in which the strength of magnetization is weak with respect to the open magnetic circuit curve 53 of the measurement result. In this case, for example, the temporary closed magnetic circuit curve 51 is corrected in the direction of increasing the strength of the magnetization by the amount of the error in the magnetization direction of the two open magnetic circuit curves 52 and 53. By performing the simulation on the basis of the corrected temporary closed magnetic circuit curve 51, the open magnetic circuit curve 52 obtained as the calculation result is reduced in error with respect to the open magnetic circuit curve 53 of the measurement result.

By repeating the correction of the temporary closed magnetic circuit curve 51 in the magnetization direction, the error between the open magnetic circuit curve 52 obtained as the calculation result and the open magnetic circuit curve 53 of the measurement result can be reduced to a predetermined value or less. Then, the temporary closed magnetic circuit curve 51 of when the error becomes a predetermined value or less is the closed magnetic circuit curve 54 representing the magnetic characteristics excluding the influence of the diamagnetic field.

When the temporary closed magnetic circuit curve 51 is repeatedly corrected in the magnetization direction as illustrated in FIG. 11, there is a possibility of obtaining a solution that does not satisfy the monotonicity of the demagnetization curve. The demagnetization curve that does not satisfy the monotonicity is a non-physical solution and cannot be adopted as the magnetization curve that represents the magnetic characteristics of the permanent magnet 41.

Furthermore, when it becomes a state where the monotonicity is not satisfied in a wide range as illustrated in FIG. 11, the solution does not easily converge and the number of iterations until convergence increases. For example, it takes about 7 to 10 iterations (time of about 10 to 15 minutes) to converge.

Therefore, the dosed magnetic circuit calculation unit 130 adopts the method of making a correction in the external magnetic field direction as the method of correcting the temporary dosed magnetic circuit curve 51.

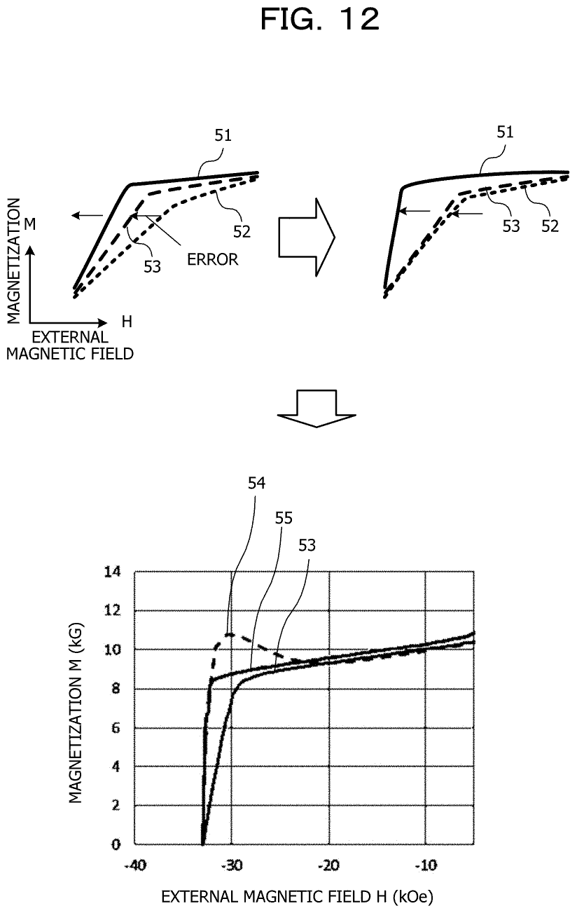

FIG. 12 is a diagram illustrating an example of a calculation result by correcting a temporary closed magnetic circuit curve in the external magnetic field direction. In the example of FIG. 12, the temporary closed magnetic circuit curve 51 is corrected on the basis of the error in the strength direction of the external magnetic field between the open magnetic circuit curve 52 obtained as the calculation result of the simulation and the open magnetic circuit curve 53 of the measurement result. In the example of FIG. 12, the open magnetic circuit curve 52 obtained as the calculation result of the simulation is shifted in the external magnetic field in the positive direction with respect to the open magnetic circuit curve 53 of the measurement result. In this case, for example, the open magnetic circuit curve 52 corrects the temporary closed magnetic circuit curve 51 in the negative direction of the external magnetic field by the amount of the error in the external magnetic field direction of the two open magnetic circuit curves 52 and 53.

By repeating the correction of the temporary closed magnetic circuit curve 51 in the external magnetic field direction, the error in the external magnetic field direction between the open magnetic circuit curve 52 obtained as the calculation result and the open magnetic circuit curve 53 of the measurement result can be reduced to a predetermined value or less. When the error in the external magnetic field direction is reduced, the error in the magnetization direction is also reduced. Then, the temporary closed magnetic circuit curve 51 of when the error in the magnetization direction becomes a predetermined value or less is a closed magnetic circuit curve 55 representing the magnetic characteristics excluding the influence of the diamagnetic field.

In the closed magnetic circuit curve 55 obtained by repeating the calculation of the open magnetic circuit curve 52 and the correction of the temporary closed magnetic circuit curve 51 in the external magnetic field direction, no ridge in the magnetization direction is caused like the closed magnetic circuit curve 54 in the case of making a correction in the magnetization direction. As a result, it is suppressed that the monotonicity is not satisfied in the closed magnetic circuit curve 55 obtained by making a correction in the external magnetic field direction.

Note that, in the case of correcting the temporary closed magnetic circuit curve 51 in the external magnetic field direction, there is a possibility that the monotonicity is not satisfied as the temporary closed magnetic circuit curve 51 meanders in the external magnetic field direction. The meandering of the temporary closed magnetic circuit curve 51 in the external magnetic field direction is often caused by a measurement error when measuring the open magnetic circuit curve 53, and in this case, the meandering becomes fine unevenness.

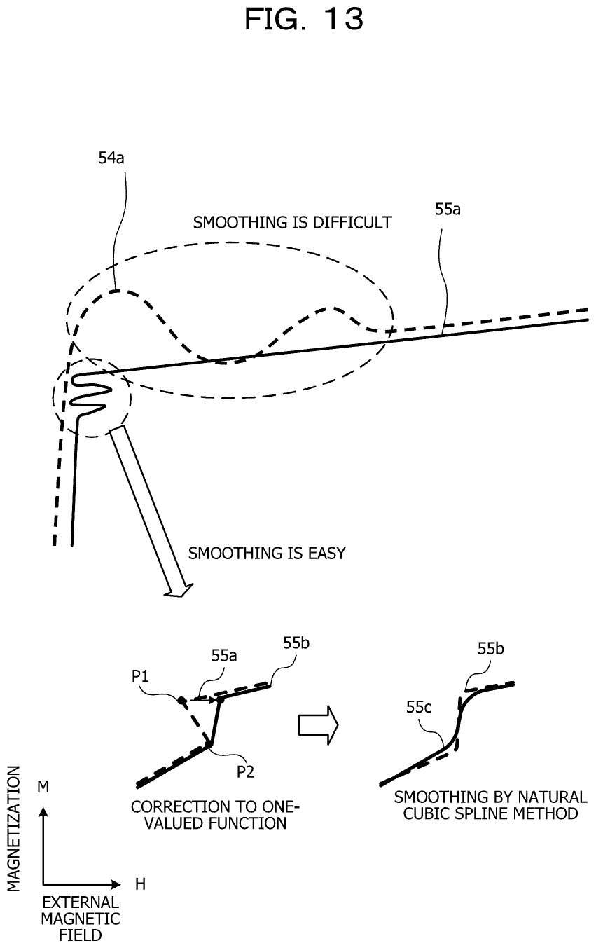

FIG. 13 is a diagram illustrating an example of a meandering closed magnetic circuit curve. FIG. 13 illustrates a closed magnetic circuit curve 54a obtained as a correction result in the magnetization direction and a closed magnetic circuit curve 55a obtained as a correction result in the external magnetic field direction. The closed magnetic circuit curve 54a obtained as the correction result in the magnetization direction fluctuates up and down in the magnetization direction so as to have large waves (long period). Such large waves as in the closed magnetic circuit curve 54a are difficult to correct to satisfy the monotonicity by smoothing. For example, even if smoothing is performed for the closed magnetic circuit curve 54a that largely waves in the magnetization direction as illustrated in FIG. 13, the curve cannot be significantly corrected because the shape is originally smooth. Moreover, if the dosed magnetic circuit curve 54a is forcibly corrected in a significant manner, the dosed magnetic circuit curve 54a may significantly deviate from the original magnetic characteristics of the permanent magnet 41, resulting in an inaccurate solution.

Meanwhile, the dosed magnetic circuit curve 55a obtained as the correction result in the external magnetic field direction has fine jags in the external magnetic field direction (the period is short), The fine jags of the dosed magnetic circuit curve 55a in the external magnetic field direction can be easily smoothed by smoothing. For example, the dosed magnetic circuit calculation unit 130 can perform smoothing by a natural cubic spline method to smoothly correct the jagged portion. Moreover, when the cause of the jaggedness in the dosed magnetic circuit curve 55a is the measurement error of the open magnetic circuit curve 53, the closed magnetic circuit curve 55a does not significantly deviate from the original magnetic characteristics of the permanent magnet 41 even if the influence is removed. As a result, the accuracy of the final closed magnetic circuit curve 55a is improved.

For example, as a correction method for the jaggedness in the external magnetic field direction, for example, the closed magnetic circuit calculation unit 130 corrects the closed magnetic circuit curve 55a into a one-valued function when the closed magnetic circuit curve 55a is not a one-valued function. The one-valued function is a function in which only one value of y corresponds to one value of x when the function is expressed as “y=f(x)”. For example, when the closed magnetic circuit curve 55a is jagged in the external magnetic field direction, the closed magnetic circuit curve 55a is not a one-valued function. Therefore, the closed magnetic circuit calculation unit 130 shifts a position of a point P1, which does not correspond to a one-valued function, in the external magnetic field direction. In the example of FIG. 13, the position of the point P1 is corrected to a position where the value of the external magnetic field is larger than that of an adjacent lower point P2 (the point with smaller magnetization), Thereby, the dosed magnetic circuit curve 55a, which is not a one-valued function, is corrected to the dosed magnetic circuit curve 55b, which is a one-valued function.

Moreover, the dosed magnetic circuit calculation unit 130 performs smoothing using a natural cubic spline function. Thereby, the dosed magnetic circuit curve 55b corrected to a one-valued function is corrected to a closed magnetic circuit curve 55c having a smooth curve. By repeating such correction of the temporary closed magnetic circuit curve 51 until the error between the open magnetic circuit curve 53 of the measurement result and the open magnetic circuit curve 52 of the simulation result becomes a predetermined value or less, the closed magnetic circuit curve representing the magnetic characteristics of the permanent magnet 41 can be obtained.

Note that either the correction processing to the one-valued function or the smoothing processing may be performed first.

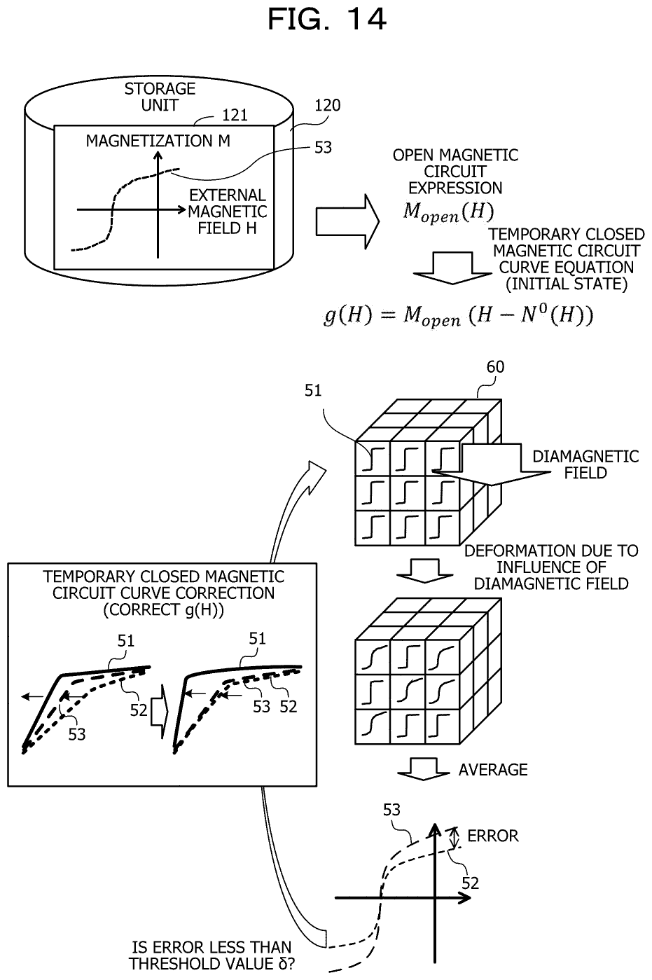

FIG. 14 is a diagram illustrating an example of a correction method for a closed magnetic circuit curve. First, the closed magnetic circuit calculation unit 130 calculates the temporary closed magnetic circuit curve 51 using parameters obtained from the open magnetic circuit curve 53 of the measurement result. For example, the closed magnetic circuit calculation unit 130 generates an open magnetic circuit curve expression “Mₒₚₑₙ(H)” for obtaining the value of the magnetization (M) using the external magnetic field (H) as a variable, on the basis of the measurement result 121 indicating the value of the magnetization for each value of the external magnetic field as illustrated in FIG. 6. Next, the closed magnetic circuit calculation unit 130 defines a function “g(H) Mₒₚₑₙ(H N⁰ (H))” representing the temporary closed magnetic circuit curve 51 in the initial state, using the open magnetic circuit curve expression “Mₒₚₑₙ(H)”, “N⁰ (H)” is an initial state of an expression representing the magnitude of the diamagnetic field (the magnetic field difference between a point on the closed magnetic circuit curve and a point on the open magnetic circuit curve) according to the external magnetic field H. “N⁰ (H)” may be, for example, a fixed value for all the external magnetic fields H. Furthermore, “N⁰ (H)” can be obtained on the basis of the magnetic characteristics of another permanent magnet similar to the permanent magnet 41 to be measured. Since the magnetic characteristics of the permanent magnet 41 to be measured are not reflected in “N⁰ (H)”, the temporary dosed magnetic circuit curve 51 in the initial state is in a state where sufficient accuracy is not obtained.

Here, the dosed magnetic circuit calculation unit 130 divides the area where the permanent magnet 41 exists into a plurality of meshes to generate a mesh model 60. This mesh model 60 is an example of the three-dimensional model 2 described in the first embodiment.

The closed magnetic circuit calculation unit 130 assumes that all the meshes have the same temporary closed magnetic circuit curve 51. At this time, it is assumed that the temporary closed magnetic circuit curve 51 is deformed for each mesh due to the influence of the diamagnetic field, and an average of the temporary closed magnetic circuit curves for all the meshes is the open magnetic circuit curve. Therefore, the closed magnetic circuit calculation unit 130 applies deformation due to the influence of the diamagnetic field to the temporary dosed magnetic circuit curve 51 of each mesh. Then, the closed magnetic circuit calculation unit 130 obtains the average of the temporary closed magnetic circuit curves of the meshes after deformation to calculate the open magnetic circuit curve 52. If the initially generated temporary closed magnetic circuit curve 51 is accurate, the calculated open magnetic circuit curve 52 is supposed to mostly match the open magnetic circuit curve 53 obtained as the measurement result.

Therefore, the closed magnetic circuit calculation unit 130 obtains a magnetization error (magnetization difference “dMₐᵥₑ(H)”) between the open magnetic circuit curve 52 obtained as the calculation result and the open magnetic circuit curve 53 obtained as an actually measured value. The closed magnetic circuit calculation unit 130 corrects the temporary closed magnetic circuit curve 51 so that the open magnetic circuit curve 52 of the calculation result approaches the open magnetic circuit curve 53 of the measurement result if the magnetization error is not less than a threshold value δ.

For example, the closed magnetic circuit calculation unit 130 obtains the magnetic field difference “N(H)” between the temporary closed magnetic circuit curve 51 corresponding to the external magnetic field H and the open magnetic circuit curve 52 of the calculation result. Then, the closed magnetic circuit calculation unit 130 generates an expression “Mₒₚₑₙ(H−N(H))” for shifting a magnetic field component of the open magnetic circuit curve expression “Mₒₚₑₙ(H)” of the measurement result by the magnetic field difference “N(H)”. The closed magnetic circuit calculation unit 130 obtains a result of processing for the expression “Mₒₚₑₙ(H−N(H))”, such as the correction to a one-valued function and the smoothing by the natural cubic spline method, as the temporary closed magnetic circuit curve 51 after correction.

The closed magnetic circuit calculation unit 130 repeats the calculation of the open magnetic circuit curve 52 based on such a temporary closed magnetic circuit curve 51 and the correction of the temporary closed magnetic circuit curve 51 to reduce the error until the error becomes less than the predetermined threshold value δ. Then, the closed magnetic circuit calculation unit 130 sets the temporary closed magnetic circuit curve 51 obtained when the error becomes less than the predetermined threshold value δ as the closed magnetic circuit curve obtained by correcting the open magnetic circuit curve 53 of the measurement result.

Next, a magnetization calculation r Method of each r Mesh will be described in detail.

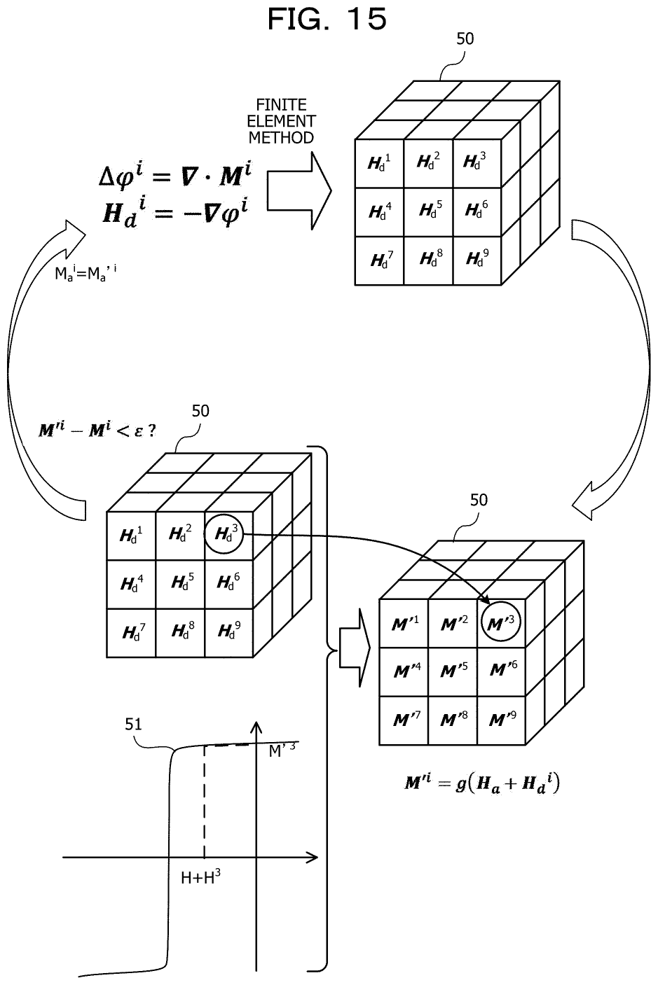

FIG. 15 is a diagram illustrating an example of a magnetization calculation method. First, the closed magnetic circuit calculation unit 130 calculates, for each mesh, the diamagnetic field according to the external magnetic field at the position of the mesh, using a finite element method.

A diamagnetic field H_{d}ⁱ of the i-th (i is an integer of 1 or larger) mesh when the external magnetic field is Hₐ is expressed by the following equation.

[Math. 1]

Δφⁱ=∇·mⁱ (1)

[Math. 2]

H_{d}ⁱ=−∇_{φ}ⁱ (2)

Δ in Equation (1) is a Laplacian. ∇ is a nabla that indicates a differential operation of a vector. M′ is the magnetization of the i-th mesh. Mⁱ s obtained by “g(Hₐ)” on the basis of the function “g(H)=Mₒₚₑₙ(H−N(H))”. φⁱ is a magnetic potential of the i-th mesh. The closed magnetic circuit calculation unit 130 calculates the diamagnetic field of each mesh by the finite element method using Equations (1) and (2).

The closed magnetic circuit calculation unit 130 obtains magnetization M″ⁱ in the case of including the influence of the diamagnetic field, using the function of the temporary closed magnetic circuit curve 51. For example, the closed magnetic circuit calculation unit 130 calculates “M′ⁱ=g(Hₐ H_{d}ⁱ)”.

The closed magnetic circuit calculation unit 130 determines whether the error between the magnetization M′ⁱ calculated including the diamagnetic field and the magnetization Mⁱ is less than the threshold value E of the error. When the error is equal to or larger than the threshold value E of the error, the closed magnetic circuit calculation unit 130 substitutes the magnetization M′ⁱ into the magnetization Mⁱ, and calculates the diamagnetic field H_{d}ⁱ by the finite element method again. Then, the closed magnetic circuit calculation unit 130 repeats the calculation of the diamagnetic field H_{d}ⁱ and the calculation of the magnetization M′ⁱ until the error becomes less than the threshold value E of the error. The closed magnetic circuit calculation unit 130 sets the magnetization Mⁱ of each mesh of when the error becomes less than the threshold value E of the error as the calculation result of the magnetization of when the external magnetic field is Hₐ, for all the meshes.

When completing the calculation of the magnetization of the meshes, the dosed magnetic circuit calculation unit 130 calculates an average value of the magnetization of the meshes.

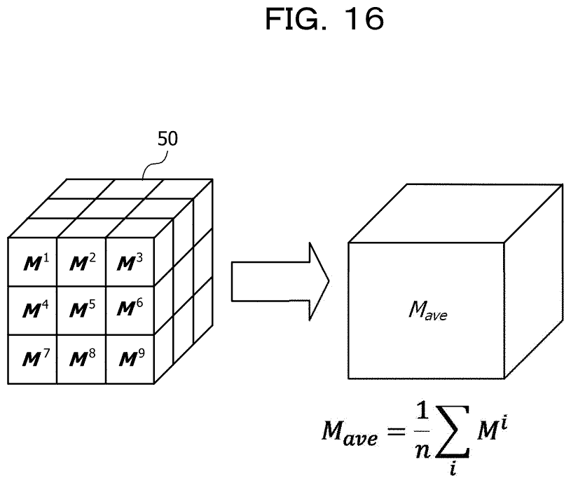

FIG. 16 is a diagram illustrating an example of calculating average magnetization. For example, average magnetization Mₐᵥₑ when the external magnetic field is Hₐ is expressed by the following equation.

$$\begin{matrix}[ Math . 3 ] & \\ {M}_{ave} = \frac{1}{n} {\sum }_{i} {M}^{i} & ( 3 )\end{matrix}$$

In Equation (3), n is the number of meshes (n is an integer of 1 or larger). The closed magnetic circuit calculation unit 130 obtains the average magnetization “Mₐᵥₑ(H)” according to the external magnetic field by obtaining the average magnetization Mₐᵥₑ while changing the external magnetic field. The obtained average magnetization “Mₐᵥₑn” becomes the open magnetic circuit curve 52 of the calculation result.

The closed magnetic circuit calculation unit 130 corrects the temporary closed magnetic circuit curve 51, using the difference in the external magnetic field direction between the open magnetic circuit curve 52 of the calculation result and the temporary closed magnetic circuit curve 51.

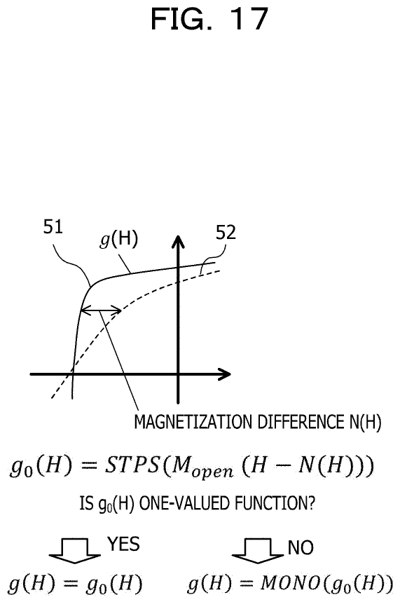

FIG. 17 is a diagram illustrating an example of a correction method for a temporary closed magnetic circuit curve. The effect of the diamagnetic field on the permanent magnet 41 is expressed by the magnetic field difference between the external magnetic field of the temporary closed magnetic circuit curve 51 and the external magnetic field of the open magnetic circuit curve 52 of the calculation result (the external magnetic field of the open magnetic circuit curve 52—the external magnetic field of the temporary closed magnetic circuit curve 51). The magnetic field difference changes depending on the value of magnetization. For example, the magnetic field difference can be expressed by the function “N′(M)”. When the magnetization M, which is a variable of this function, is replaced with, for example, the function “Mₒₚₑₙ(H)” representing the open magnetic circuit curve 53 of the measurement result, the magnetic field difference is expressed by the function “N(H)” with the magnetization H as a variable. In this case, the function “N(H)” represents the difference between the external magnetic field of the temporary closed magnetic circuit curve 51 and the external magnetic field of the open magnetic circuit curve 52 of the calculation result in the magnetization same as the magnetization M in the open magnetic circuit curve 53 of the measurement result in a certain external magnetic field H.

The closed magnetic circuit calculation unit 130 generates a provisional closed magnetic circuit curve “g₀(H)” by setting “g₀(H)=STPS(Mₒₚₑₙ(H−N(H)))”. “STPS( )” is a function that performs smoothing by the natural cubic spline method. “g₀(H)=STPS(f(H))” indicates that the result of smoothing the function “f(H)” by the natural cubic spline method is substituted into “g₀(H)”. In the above example, “f(H)=Mₒₚₑₙ(H−N(H))”

“Mₒₚₑₙ(H−N(H))” indicates that the open magnetic circuit curve of the measurement result is shifted in the external magnetic field direction by the magnetic field difference “N(H)” according to the value of the external magnetic field H. For example, the closed magnetic circuit calculation unit 130 acquires the magnetization “Mₒₚₑₙ(H)” corresponding to the value (H) of the external magnetic field indicated in the measurement result 121, Then, the closed magnetic circuit calculation unit 130 calculates “Mₒₚₑₙ(H−N(H))” using the magnetic field difference “N(H)” between the external magnetic field of the temporary closed magnetic circuit curve 51 at the acquired magnetization and the external magnetic field of the open magnetic circuit curve 52 of the calculation result.

The closed magnetic circuit calculation unit 130 determines whether “g₀(H)” is a one-valued function, and sets “g₀(H)” as the function “g(H)” representing the temporary closed magnetic circuit curve 51 after correction when “g₀(H)” is a one-valued function (g(H)=g₀(H)). Furthermore, the closed magnetic circuit calculation unit 130 sets a function “MONO(g₀(H))” corrected to a one-valued function as the function “g(H)” representing the temporary closed magnetic circuit curve 51 after correction when “g₀(H)” is not a one-valued function (g(H)=MONO(g₀(H))). “MONO( )” is a function that corrects a function to be processed into a one-valued function. “g(H)=MONO(g₀(H))” indicates that the result of correcting the function “g₀(H)” to satisfy a one-valued function is substituted into “g(H)”.

Note that, when obtaining the magnetic field difference (N(H)) between the obtained open magnetic circuit curve 52 (average magnetization Mₐᵥₑn) and the temporary closed magnetic circuit curve 51 (M(H)=g(H)), the closed magnetic circuit calculation unit 130 sets the point measured in the measurement result 121 as a reference, for example.

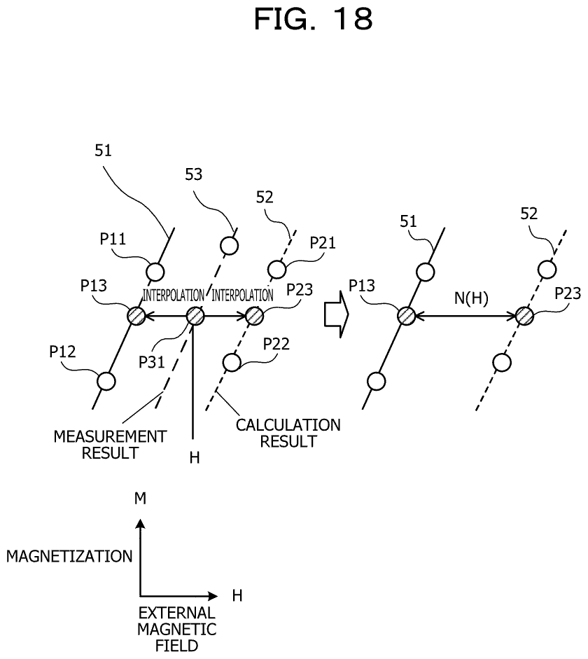

FIG. 18 is a diagram illustrating an example of a magnetic field difference calculation method. For example, the closed magnetic circuit calculation unit 130 specifies a discrete point P31 (the value of the external magnetic field and the measured value of the magnetization at that time) indicated in the measurement result 121. The closed magnetic circuit calculation unit 130 obtains a discrete point P13 on the temporary closed magnetic circuit curve 51, the discrete point corresponding to the specified discrete point P31. For example, the closed magnetic circuit calculation unit 130 sets a point interpolated from two discrete points P11 and P12 on the temporary closed magnetic circuit curve 51 as the discrete point P13. The discrete point P13 is, for example, a point on the temporary closed magnetic circuit curve 51 whose value of the magnetization is equal to the discrete point P31. Furthermore, the closed magnetic circuit calculation unit 130 obtains a discrete point P23 on the open magnetic circuit curve 52, the discrete point corresponding to the specified discrete point P31. For example, the closed magnetic circuit calculation unit 130 sets a point interpolated from two discrete points P21 and P22 on the open magnetic circuit curve 52 as the discrete points P23. The discrete point P23 is, for example, a point on the open magnetic circuit curve 52 whose value of the magnetization is equal to the discrete point P31.

The closed magnetic circuit calculation unit 130 sets the difference in the value of the external magnetic field between the discrete point P13 and the discrete point P23 (the value of the external magnetic field of the discrete point P23—the value of the external magnetic field of the discrete point P13) as the magnetic field difference “N(H)” corresponding to the value H of the external magnetic field of the discrete point P31.

The closed magnetic circuit calculation unit 130 can obtain the function “g₀(H)” as a correction candidate as illustrated in FIG. 17, using the magnetic field difference “N(H)”. When the function “g₀(H)” as a correction candidate is not a one-valued function, the closed magnetic circuit calculation unit 130 corrects the function “g₀(H)” to a one-valued function.

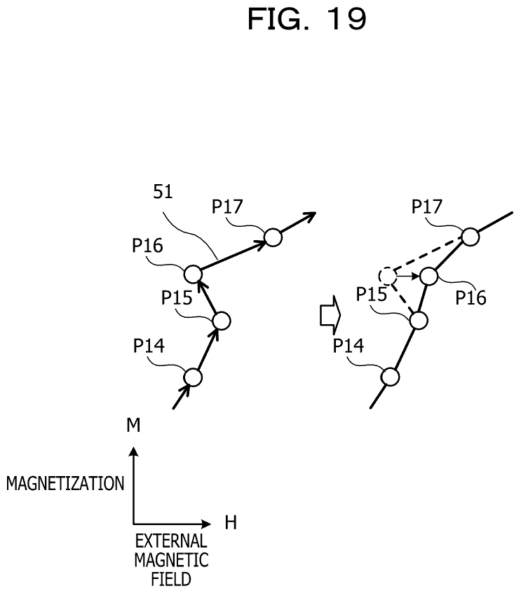

FIG. 19 is a diagram illustrating an example of a correction method to a one-valued function. For example, the closed magnetic circuit calculation unit 130 traces discrete points of the temporary closed magnetic circuit curve 51 from weaker side to stronger side of the magnetization. In the example of FIG. 19, the closed magnetic circuit calculation unit 130 traces discrete points of interest in order of a discrete point P14, a discrete point P15, a discrete point P16, and a discrete point P17. The closed magnetic circuit calculation unit 130 determines that the monovalence is maintained when the external magnetic field of the discrete point of interest after movement is stronger than the external magnetic field of the discrete point of interest before movement when moving the discrete point of interest to an adjacent discrete point. Furthermore, the closed magnetic circuit calculation unit 130 determines that the monovalence is not maintained when the external magnetic field of the discrete point of interest before movement is equal to or stronger than the external magnetic field of the discrete point of interest after movement.

When determining that the monovalence is not maintained, the closed magnetic circuit calculation unit 130 corrects the value of the external magnetic field at the discrete point after movement in the positive direction of the external magnetic field. In the example of FIG. 19, when the discrete point of interest is moved from the discrete point P15 to the discrete point P16, it is determined that the monovalence is not maintained. The closed magnetic circuit calculation unit 130 corrects the position of the discrete point P16 in the positive direction of the external magnetic field (increases the value of the external magnetic field). For example, the closed magnetic circuit calculation unit 130 sets the value of the external magnetic field of the discrete point P16 to be larger than the value of the external magnetic field of the discrete point P15 and smaller than the value of the discrete point P17.

At this time, the closed magnetic circuit calculation unit 130 may minimize an amount of movement of the discrete point P16. For example, the closed magnetic circuit calculation unit 130 corrects the value of the external magnetic field of the discrete point P16 to a value larger than the value of the external magnetic field of the discrete point P15 by a step size (minimum unit of the amount of movement) of the external magnetic field. Since the amount of movement of the discrete point P16 is minimized, it is possible to suppress the deterioration of the accuracy of the magnetic characteristics appearing in the calculation result of the temporary closed magnetic circuit curve 51 due to the movement of the discrete point P16.

Hereinafter, details of a procedure of correction processing for the temporary closed magnetic circuit curve 51 by the closed magnetic circuit calculation unit 130 will be described with reference to the flowchart.

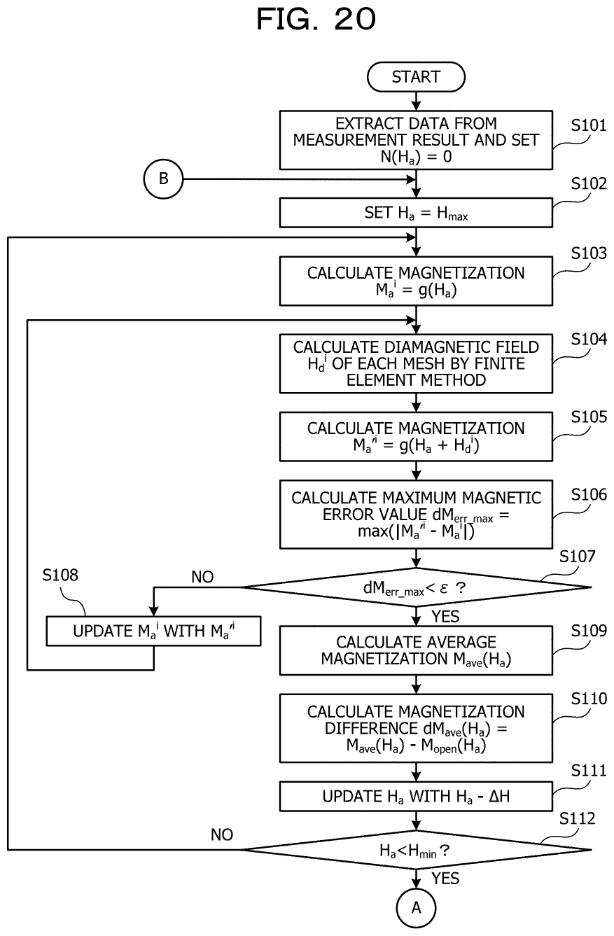

FIG. 20 is a first half of a flowchart illustrating an example of the procedure of correction processing for the temporary closed magnetic circuit curve. Hereinafter, processing illustrated in FIG. 20 will be described in accordance with step numbers.

[step S101] The closed magnetic circuit calculation unit 130 extracts data from the measurement result 121 stored in the storage unit 120. Furthermore, the closed magnetic circuit calculation unit 130 extracts a maximum value Hₘₐₓ of the external magnetic field and a minimum value Hₘᵢₙ of the external magnetic field from the measurement result 121. The closed magnetic circuit calculation unit 130 stores the extracted maximum value Hₘₐₓ and minimum value Hₘᵢₙ in the memory 102.

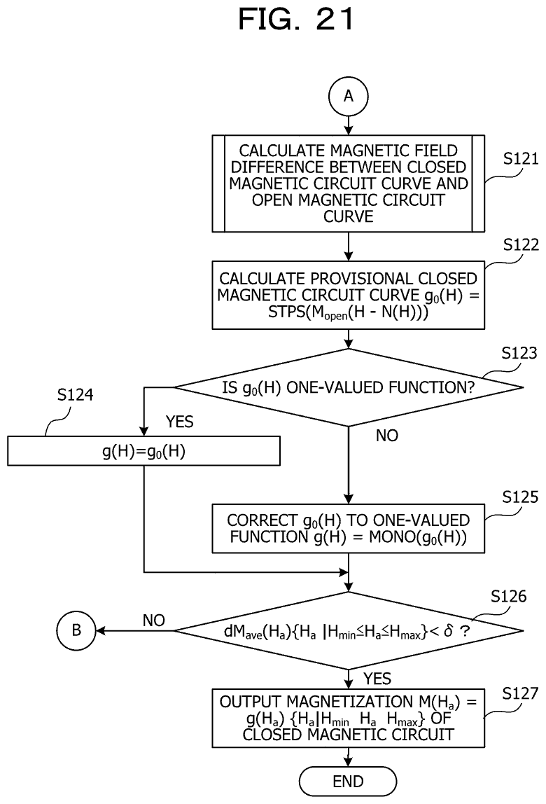

Furthermore, the closed magnetic circuit calculation unit 130 sets “0” as an initial value in the magnetic field difference “N(Hₐ){Hₐ|Hₘᵢₙ≤Hₐ≤Hₘₐₓ}” in the external magnetic field Hₐ (N(Hₐ)=0).

[step S102] The closed magnetic circuit calculation unit 130 sets the maximum value Hₘₐₓ as the initial value of the external magnetic field Hₐ.

[step S103] The closed magnetic circuit calculation unit 130 calculates the magnetization “Mₐⁱ{i|1≤i≤n}” of each of the n meshes on the basis of the external magnetic field Hₐ and the magnetic field difference “N(Hₐ)”. For example, the closed magnetic circuit calculation unit 130 calculates “Mₐⁱ g(Hₐ)” g(Hₐ) for i=1, . . . , n. Note that g(Hₐ) is expressed by an equation “g(Hₐ)=Mₒₚₑₙ(H N(Hₐ))”.

[step S104] The closed magnetic circuit calculation unit 130 calculates the diamagnetic field H_{d}ⁱ of each mesh by the finite element method on the basis of Mₐⁱ.

[step S105] The closed magnetic circuit calculation unit 130 calculates the magnetization Mₐ″ for each mesh on the basis of the diamagnetic field H_{d}ⁱ, For example, the closed magnetic circuit calculation unit 130 calculates “Mₐⁱ=g(Hₐ+H_{d}ⁱ” for i=1, 2, . . . , n. “g(Hₐ+H_{d}ⁱ)” is expressed by an equation “g(Hₐ+H_{d}ⁱ)=Mₒₚₑₙ(H−N(Hₐ+H_{d}ⁱ))”.

[step S106] The closed magnetic circuit calculation unit 130 calculates a maximum magnetization error value dM_{err_max} among all the meshes on the basis of the magnetization Mₐ′ⁱ and the magnetization. The maximum magnetization error value dM_{err_max} is expressed by an equation “dM_{err_max}=max(|Mₐ′ⁱ−Mₐⁱ|){i|1≤i≤n}”.

[step S107] The closed magnetic circuit calculation unit 130 determines whether the maximum magnetization error value dM_{er_max} is less than the threshold value E of the error. When the maximum magnetization error value dM_{err_max} is less than the threshold value E of the error, the closed magnetic circuit calculation unit 130 advances the processing to step S109. Furthermore, when the maximum magnetization error value dM_{err_max} is equal to or larger than the threshold value E of the error, the closed magnetic circuit calculation unit 130 advances the processing to step S108.

[step S108] The closed magnetic circuit calculation unit 130 updates the value of Mₐⁱ with the value of Mₐⁱ′ⁱ for each of i=1, n. Thereafter, the closed magnetic circuit calculation unit 130 advances the processing to step S104.

[step S109] The closed magnetic circuit calculation unit 130 determines that the magnetization Mₐ′ of each mesh of when the condition of step S107 is satisfied is the value of the magnetization of each mesh reflecting the influence of the diamagnetic field in the external magnetic field Hₐ. Therefore, the closed magnetic circuit calculation unit 130 calculates the average magnetization Mₐᵥₑ(Hₐ) of the magnetization Mₐ′ of all the meshes. Mₐᵥₑ(Hₐ) is expressed by the following equation.

$$\begin{matrix}[ Math . 4 ] & \\ {M}_{ave} ( {H}_{a} ) = \frac{1}{n} {\sum }_{i} {M}_{a}^{i} & ( 4 )\end{matrix}$$

[step S110] The closed magnetic circuit calculation unit 130 calculates the magnetization difference “dMₐᵥₑ(Hₐ){Hₐ Hₘᵢₙ≤Hₐ≤Hₘₐₓ}” on the basis of the average magnetization “Mₐᵥₑ(Hₐ)” and “Mₒₚₑₙ(Hₐ)”. The magnetization difference is expressed by an equation “dMₐᵥₑ(Hₐ)=Mₐᵥₑ(Hₐ)−Mₒₚₑₙ(Hₐ)”.

[step S111] The closed magnetic circuit calculation unit 130 subtracts the value of the external magnetic field Hₐ by a step size ΔH of the external magnetic field. For example, the closed magnetic circuit calculation unit 130 updates the value of the external magnetic field Hₐ with “Hₐ-ΔH”. Note that the step size ΔH of the external magnetic field is a preset value. For example, the step size ΔH of the external magnetic field is the same as the difference between continuous values of the external magnetic field included in the measurement result 121.

[step S112] The closed magnetic circuit calculation unit 130 determines whether the value of the updated external magnetic field Hₐ is less than the minimum value Hₘᵢₙ of the external magnetic field. When the value of the external magnetic field Hₐ is less than the minimum value Hₘᵢₙ of the external magnetic field, the closed magnetic circuit calculation unit 130 advances the processing to step S121 (see FIG. 21). Furthermore, when the value of the external magnetic field Hₐ is equal to or larger than the minimum value Hₘᵢₙ of the external magnetic field, the closed magnetic circuit calculation unit 130 advances the processing to step S103.

FIG. 21 is a latter half of the flowchart illustrating an example of the procedure of correction processing for the temporary closed magnetic circuit curve. Hereinafter, processing illustrated in FIG. 21 will be described in accordance with step numbers.

[step S121] The closed magnetic circuit calculation unit 130 performs the processing of calculating the magnetic field difference “N(H)” between the temporary closed magnetic circuit curve 51 and the open magnetic circuit curve 52 of the calculation result.

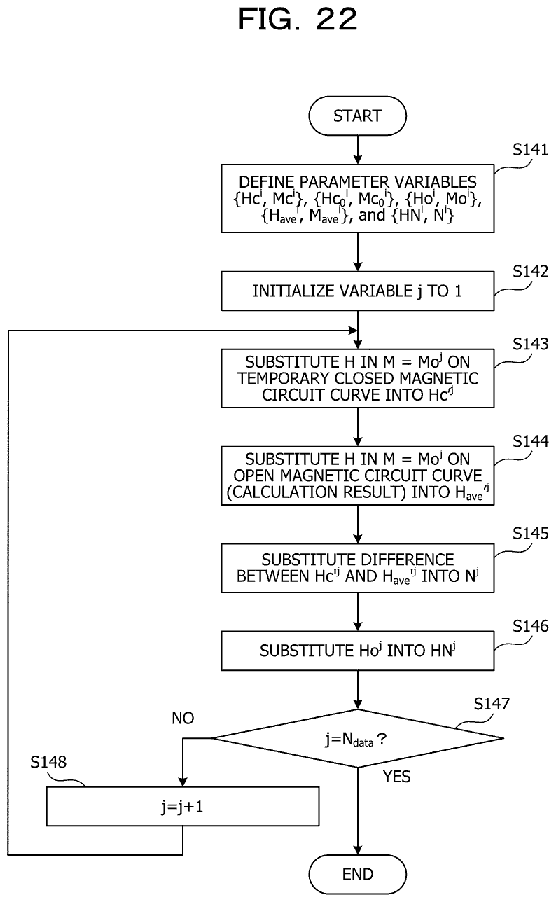

FIG. 22 is a flowchart illustrating a procedure of processing for calculating a magnetic field difference between a closed magnetic circuit curve and an open magnetic circuit curve. Hereinafter, processing illustrated in FIG. 22 will be described in accordance with step numbers.

[step S141] The closed magnetic circuit calculation unit 130 defines parameter variables {Hcⁱ, Mcⁱ}, {Hc₀ⁱ, Mc₀′}, {Hoⁱ, Moⁱ}, {Hₐᵥₑⁱ, nₐᵥₑⁱ}, and {HNⁱ, Nⁱ} to be used to calculate the magnetic field difference N(H). The meaning of each parameter variable is as follows.

{Hcⁱ, Mcⁱ}(i=1, . . . N_{data}) are parameter variables representing the temporary closed magnetic circuit curve 51 “g(H)”. The external magnetic field of the i-th discrete point is “Hcⁱ” and the magnetization of the i-th discrete point is “Mcⁱ”, of the temporary dosed magnetic circuit curve 51 “g(H)”. “N_{data}” is the number of discrete points indicated in the measurement result 121.

{Hc₀ⁱ, Mc₀ⁱ} (i=1, . . . , N_{data}) are parameter variables representing the provisional closed magnetic circuit curve “g₀(H)”. The external magnetic field of the i-th discrete point is “Hc₀ⁱ” and the magnetization of the i-th discrete point is “Mc₀ⁱ”, of the provisional dosed magnetic circuit curve “g₀(H)”.

{Hoⁱ, Moⁱ}(i=1, . . . , N_{data}) are parameter variables representing the open magnetic circuit curve 53 “Mₒₚₑₙ(H)” of the measurement result. The external magnetic field of the i-th discrete point is “Hoⁱ” and the magnetization of the i-th discrete point is “Mo₀ⁱ”, of the open magnetic circuit curve 53 “Mₒₚₑₙ(H)” of the measurement result.

{Hₐᵥₑⁱ, Mₐᵥₑⁱ} (i=1, . . . , N_{data}) are parameter variables representing the open magnetic circuit curve 52 “Mₐᵥₑ(H)” of the calculation result. The external magnetic field of the i-th discrete point is “Hₐᵥₑⁱ” and the magnetization of the i-th discrete point is “Mₐᵥₑⁱ”, of the open magnetic circuit curve 52 “Mₐᵥₑ(H)” of the calculation result.

{HNⁱ, Nⁱ} (i=1, . . . , N_{data}) are parameter variables representing the magnetic field difference “N(H)” between the closed magnetic circuit curve and the open magnetic circuit curve. The external magnetic field “Hoⁱ” of the i-th discrete point is set to “HNⁱ” and the magnetic field difference of the discrete point is set to “Nⁱ”, of the open magnetic circuit curve 52 “Mₒₚₑₙ(H)” of the measurement result.

[step S142] The closed magnetic circuit calculation unit 130 initializes a variable j indicating a number of a calculation position of the magnetic field difference to “1” (j=1). For example, among the values of the external magnetic field indicated in the measurement result 121, the order of values for which the magnetic field difference is to be calculated is represented by the variable j.

[step S143] The closed magnetic circuit calculation unit 130 calculates the value of the external magnetic field H in M=Mo^{j} from {Hcⁱ, Mcⁱ}(i=1, . . . , N_{data}) on the basis of the variables {Hcⁱ, Mcⁱ}, {Hoⁱ, Moⁱ} (i=1, . . . , N_{data}) by interpolation and substitutes the calculated value into H_{c}^{j}. Thereby, the external magnetic field H at the point where the magnetization on the temporary closed magnetic circuit curve 51 is M=Mo^{j} is set to Hc′^{j}.

[step S144] The closed magnetic circuit calculation unit 130 calculates the value of H in M=Mo^{j} from {Hₐᵥₑⁱ, Mₐᵥₑⁱ} (i=1, . . . , N_{data}) using the variables {Hₐᵥₑⁱ, Mₐᵥₑⁱ}, {Hoⁱ, Moⁱ}(i=1, . . . , N_{data}) by interpolation and substitutes the calculated value into Hₐᵥₑ′^{j}. Thereby, the external magnetic field H at the point where the magnetization on the open magnetic circuit curve 52 (calculation result) is M=Moⁱ is set to Hₐᵥₑ′^{j}.

[step S145] The closed magnetic circuit calculation unit 130 substitutes the difference “Hc′^{j}-Hₐᵥₑ′^{j}” between Hc′^{j} and Hₐᵥₑ′^{j} into N^{j}.

[step S146] The closed magnetic circuit calculation unit 130 substitutes Ho^{j} into HN^{j}.

[step S147] The closed magnetic circuit calculation unit 130 determines whether the value of the variable j has reached N_{data}=N_{data}?). When the value of the variable j has reached N_{data}, the closed magnetic circuit calculation unit 130 terminates the processing for calculating the magnetic field difference between the closed magnetic circuit curve and the open magnetic circuit curve. Furthermore, when the value of the variable j has not reached N_{data}, the closed magnetic circuit calculation unit 130 advances the processing to step S148.

[step S148] The closed magnetic circuit calculation unit 130 counts up the value of the variable j by 1 (j=j+1), and advances the processing to step S143.

In this way, the parameter variables {HNⁱ, Nⁱ}=N_{data}) representing the magnetic field difference N(H) between the closed magnetic circuit curve and the open magnetic circuit curve are obtained.

Hereinafter, the description returns to FIG. 21.

[step S122] The closed magnetic circuit calculation unit 130 calculates a provisional closed magnetic circuit curve “g₀=STPS(Mₒₚₑₙ(H-N(H)))”. For example, the closed magnetic circuit calculation unit 130 calculates {HNⁱ, Moⁱ−Nⁱ} for all of i=1, . . . , N_{data}, using the parameter variables {HNⁱ, Nⁱ}, {Moⁱ, Nⁱ} (i=1, . . . , N_{data}). The closed magnetic circuit calculation unit 130 processes the result into smooth data using the natural spline method, and substitutes the data into the variables {Hc₀ⁱ, Mc₀ⁱ} (i=1, . . . , N_{data}).

[step S123] The closed magnetic circuit calculation unit 130 determines whether the calculated provisional closed magnetic circuit curve is a one-valued function. For example, the closed magnetic circuit calculation unit 130 rearranges the variables {Hc₀ⁱ, Mc₀ⁱ} (i=1, . . . , N_{data}) for the second component Mc₀ⁱ in ascending order, and substitutes the variables into {Hc₀′ⁱ, Mc₀′ⁱ} (i=1, . . . , N_{data}). The closed magnetic circuit calculation unit 130 determines whether “Hc₀′ⁱ<Hc₀′ⁱ⁺¹” holds for i=1, . . . , N_{date}−1. The closed magnetic circuit calculation unit 130 determines that the provisional closed magnetic circuit curve “g₀” is a one-valued function when “Hc₀ⁱ”<Hc₀′ⁱ⁺¹ holds for all of i. Furthermore, the closed magnetic circuit calculation unit 130 determines that the provisional closed magnetic circuit curve “g₀” is not a one-valued function when “Hc₀ⁱ<Hc₀′ⁱ⁺¹” is not satisfied for at least one i.

When the provisional closed magnetic circuit curve is a one-valued function, the closed magnetic circuit calculation unit 130 advances the processing to step S124. Furthermore, when the provisional closed magnetic circuit curve “g₀” is not a one-valued function, the closed magnetic circuit calculation unit 130 advances the processing to step S125.

[step S124] The closed magnetic circuit calculation unit 130 updates the expression “g(H)” with the calculated provisional closed magnetic circuit curve “g₀(H)” (g(H)=g₀(H)). Thereafter, the closed magnetic circuit calculation unit 130 advances the processing to step S126, For example, the dosed magnetic circuit calculation unit 130 substitutes the variables {Hc₀ⁱ, Mc₀ⁱ} (i=1, . . . , N_{data}) into {Hcⁱ, Mcⁱ} (i=1, . . . , N_{data}).

[step S125] The closed magnetic circuit calculation unit 130 corrects the calculated provisional closed magnetic circuit curve “g₀” into a one-valued function, and updates the temporary dosed magnetic circuit curve “g(H)” with the corrected dosed magnetic circuit curve “MONO(g₀(H))” (g(H)=MONO(g₀(H))), For example, the dosed magnetic circuit calculation unit 130 substitutes “Hc₀′ⁱ⁺¹=Hc₀′ⁱ+η” when “Hc₀′ⁱ⁺¹<Hc₀′ⁱ” holds, using the variables {Hc₀′ⁱ, Mc₀′ⁱ}(i=1, . . . , N_{data}) obtained in step S123. Note that η is a constant parameter given at the start of processing. The closed magnetic circuit calculation unit 130 performs, for i=1, . . . , N_{data-1}, the determination processing as to whether “Hc₀′ⁱ⁺¹<Hc₀′ⁱ” holds and the substitution processing of “Hc₀′ⁱ⁺¹=Hc₀′ⁱ+η” when “Hc₀′ⁱ⁺¹<Hc₀′ⁱ” holds. Then, the closed magnetic circuit calculation unit 130 substitutes the obtained result {Hc₀′ⁱ, Mc₀′ⁱ} (i=1, . . . , N_{data}) into {Hcⁱ, Mcⁱ} (i=1, . . . , N_{data}).

[step S126] The closed magnetic circuit calculation unit 130 determines whether the magnetization difference “dMₐᵥₑ(Hₐ) {Hₐ|Hₘᵢₙ≤Hₐ≤Hₘₐₓ}” is less than the threshold value δ of the magnetization difference for all the external magnetic fields Hₐ. When the magnetization difference dMₐᵥₑ(Hₐ) is less than the threshold value δ of the magnetization difference for all the external magnetic fields Hₐ, the closed magnetic circuit calculation unit 130 advances the processing to step S127. Furthermore, when there is at least one external magnetic field Hₐ in which the magnetization difference dMₐᵥₑ(Hₐ) is equal to or larger than the threshold value δ, the closed magnetic circuit calculation unit 130 advances the processing to step S102 (see FIG. 20).

[step S127] The closed magnetic circuit calculation unit 130 calculates “magnetization M(Hₐ)” for each of the external magnetic fields {Hₐ|Hₘᵢₙ≤Hₐ≤Hₘₐₓ} on the basis of the magnetic field difference “N(Hₐ)”. For example, the closed magnetic circuit calculation unit 130 calculates “g(Hₐ)” for all the values of Hₐ on the basis of the equation “g(Hₐ)=Mₒₚₑₙ(H−N(Hₐ))”, and sets “g(Hₐ)” as the temporary dosed magnetic circuit curve “M(Hₐ)” (M(Hₐ)=g(Hₐ)). Then, the dosed magnetic circuit calculation unit 130 outputs the magnetization “M(Hₐ)” for all the values of Hₐ.

The magnetization “M(Hₐ)” of the dosed magnetic circuit for all the values of Hₐ output in this way is obtained. This magnetization “M(Hₐ)” represents the dosed magnetic circuit curve that satisfies the monotonicity. Since the value of the magnetic field difference “N(Hₐ)” is set to an appropriate value for each value of the external magnetic field, it is possible to correct the open magnetic circuit curve 52 obtained as the actually measured value into the correct closed magnetic circuit curve with high accuracy. For example, it is possible to obtain the closed magnetic circuit curve with high accuracy excluding the influence of the diamagnetic field on the basis of the measurement result 121 measured in the open magnetic circuit environment.

### OTHER EMBODIMENTS

In the second embodiment, the termination condition of the iterative processing of the magnetization calculation for each mesh (determination condition of step S107) is that the maximum magnetization error value dM_{err_max} is less than the threshold value E of the error, but another termination condition can also be applied. For example, the closed magnetic circuit calculation unit 130 may determine to terminate the iterative processing of the magnetization calculation (YES in step S107) when the average of magnetization of the meshes is less than the threshold value E of the error.

Furthermore, in the second embodiment, the termination condition of the iterative processing of updating the temporary closed magnetic circuit curve (determination condition of step S126) is when the magnetization difference “dMₐᵥₑ(Hₐ)” is less than the threshold value δ in all the external magnetic fields. However, another termination condition can be applied. For example, when the average of the magnetization difference “dMₐᵥₑ(Hₐ)” according to each of the external magnetic fields is less than the threshold value δ, the closed magnetic circuit calculation unit 130 may determine to terminate the iterative processing of updating the temporary dosed magnetic circuit curve (YES in step S126).

The embodiments have been exemplified above, and the configuration of each unit described in the embodiments may be replaced with another configuration having a similar function. Furthermore, any other components and steps may be added. Moreover, any two or more configurations (features) of the embodiments described above may be combined.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium storing a closed magnetic circuit calculation program for causing a computer to execute a process comprising:
calculating, on a basis of a temporary closed magnetic circuit curve that indicates a relationship between an external magnetic field and magnetization of a permanent magnet in a closed magnetic circuit environment, a first open magnetic circuit curve that indicates a relationship between the external magnetic field and the magnetization of the permanent magnet in a case of applying an influence of a diamagnetic field to the external magnetic field, using a three-dimensional model that represents the permanent magnet;
calculating a magnetic field difference indicating a difference between the temporary closed magnetic circuit curve and the first open magnetic circuit curve in an external magnetic field direction according to the magnetization;
updating the temporary closed magnetic circuit curve with a magnetization curve shifted in the external magnetic field direction by the magnetic field difference from a second open magnetic circuit curve obtained by measuring the magnetization of the permanent magnet according to the external magnetic field in an open magnetic circuit environment; and
repeating the calculation of the first open magnetic circuit curve, the calculation of the magnetic field difference, and the update of the temporary closed magnetic circuit curve until an error between the first open magnetic circuit curve and the second open magnetic circuit curve satisfies a predetermined condition.

2. The non-transitory computer-readable recording medium according to claim 1, wherein
the updating the temporary closed magnetic circuit curve includes correcting the magnetization curve to a one-valued function in a case where the magnetization curve is not a one-valued function, and correcting the temporary dosed magnetic circuit curve to the magnetization curve corrected to the one-valued function.

3. The non-transitory computer-readable recording medium according to claim 2, wherein
the updating the temporary closed magnetic circuit curve includes, in a case where a value of the external magnetic field of a second discrete point is smaller than a value of the external magnetic field of a first discrete point, the second discrete point having a value of magnetization larger than a value of magnetization of the first discrete point, among a plurality of discrete points on the magnetization curve, correcting the value of the external magnetic field of the second discrete point to be larger than the value of the external magnetic field of the first discrete point.

4. The non-transitory computer-readable recording medium according to claim 3, wherein
the updating the temporary closed magnetic circuit curve includes, in a case where the value of the external magnetic field of the second discrete point is smaller than the value of the external magnetic field of the first discrete point, correcting the value of the external magnetic field of the second discrete point to a value larger than the value of the magnetization of the second discrete point but smaller than a value of the external magnetic field of any third discrete point that has the value of the external magnetic field larger than the value of the external magnetic field of the second discrete point.

5. The non-transitory computer-readable recording medium according to claim 1, wherein
the calculating the magnetic field difference includes calculating, for a first point on the second open magnetic circuit curve, a difference value between a value of the external magnetic field of a second point on the temporary closed magnetic circuit curve, the second point having an equal value of magnetization to the first point, and a value of the external magnetic field of a third point on the first open magnetic circuit curve, the third point having an equal value of magnetization to the first point, and
the updating the temporary closed magnetic circuit curve includes generating the magnetization curve that passes through a fourth point indicated by a value of the external magnetic field obtained by changing the value of the external magnetic field of the first point on the second open magnetic circuit curve by the difference value calculated for the first point, and the value of magnetization of the first point.

6. A closed magnetic circuit calculation method performed by a computer, the method comprising:
calculating, on a basis of a temporary closed magnetic circuit curve that indicates a relationship between an external magnetic field and magnetization of a permanent magnet in a closed magnetic circuit environment, a first open magnetic circuit curve that indicates a relationship between the external magnetic field and the magnetization of the permanent magnet in a case of applying an influence of a diamagnetic field to the external magnetic field, using a three-dimensional model that represents the permanent magnet;
calculating a magnetic field difference indicating a difference between the temporary closed magnetic circuit curve and the first open magnetic circuit curve in an external magnetic field direction according to the magnetization;
updating the temporary closed magnetic circuit curve with a magnetization curve shifted in the external magnetic field direction by the magnetic field difference from a second open magnetic circuit curve obtained by measuring the magnetization of the permanent magnet according to the external magnetic field in an open magnetic circuit environment; and
repeating the calculation of the first open magnetic circuit curve, the calculation of the magnetic field difference, and the update of the temporary closed magnetic circuit curve until an error between the first open magnetic circuit curve and the second open magnetic circuit curve satisfies a predetermined condition.

7. An information processing apparatus comprising:
a memory, and
a processor coupled to the memory and configured to:
calculate, on a basis of a temporary closed magnetic circuit curve that indicates a relationship between an external magnetic field and magnetization of a permanent magnet in a closed magnetic circuit environment, a first open magnetic circuit curve that indicates a relationship between the external magnetic field and the magnetization of the permanent magnet in a case of applying an influence of a diamagnetic field to the external magnetic field, using a three-dimensional model that represents the permanent magnet;
calculate a magnetic field difference indicating a difference between the temporary closed magnetic circuit curve and the first open magnetic circuit curve in an external magnetic field direction according to the magnetization;
update the temporary closed magnetic circuit curve with a magnetization curve shifted in the external magnetic field direction by the magnetic field difference from a second open magnetic circuit curve obtained by measuring the magnetization of the permanent magnet according to the external magnetic field in an open magnetic circuit environment; and
repeat the calculation of the first open magnetic circuit curve, the calculation of the magnetic field difference, and the update of the temporary closed magnetic circuit curve until an error between the first open magnetic circuit curve and the second open magnetic circuit curve satisfies a predetermined condition.
